(19) United States
(12) Patent Application Publication
(10) Pub. No.: US 2025/0206862 A1
(43) Pub. Date: Jun. 26, 2025

(54) CAVITY FORMING COMPOSITION

(71) Applicant: NISSAN CHEMICAL CORPORATION, Tokyo (JP)

(72) Inventors: Kazuhiko KINOSHITA, Toyama-shi (JP); Shun KUBODERA, Toyama-shi (JP); Tokio NISHITA, Toyama-shi (JP)

(73) Assignee: NISSAN CHEMICAL CORPORATION, Tokyo (JP)

(21) Appl. No.: 18/848,666

(22) PCT Filed: Mar. 17, 2023
(86) PCT No.: PCT/JP2023/010519

§ 371 Date: Sep. 19, 2024

(30) Foreign Application Priority Data
Mar. 24, 2022 (JP) 2022-048670

(51) Int. Cl. C08F 220/14; H01L 21/02; H01L 21/768

(52) U.S. Cl. CPC C08F 220/14; H01L 21/02271; H01L 21/76828; H01L 21/76837

(57) ABSTRACT

A cavity forming composition for forming a cavity between conductive wiring patterns on a semiconductor substrate, the cavity forming composition containing: a solvent; and an addition polymer formed of two or more types of monomers having an ethylenically unsaturated bond, wherein the addition polymer has a repeating unit (R1) having a thermosetting moiety and a repeating unit (R2) having an easily thermally decomposable moiety, and a thermal decomposition temperature of the easily thermally decomposable moiety is higher than a thermally curing temperature of the thermosetting moiety.

### TECHNICAL FIELD

The present invention relates to a cavity forming composition for forming a cavity between conductive wiring patterns. The present invention also relates to a method for manufacturing a semiconductor element using the cavity forming composition.

### BACKGROUND ART

In recent years, a semiconductor element tends to be highly integrated, and wiring has been miniaturized accordingly. When the wiring is miniaturized, a parasitic capacitance between wires increases. When the parasitic capacitance between the wires increases, noise or delay occurs in an electric signal.

Therefore, as a method for reducing the parasitic capacitance between the wires, a method for forming a gap between the wires has been proposed (see Patent Literature 1). In this proposed technique, in a method for manufacturing a semiconductor device, a space is formed between wires by a step of selectively covering a surface of a predetermined first insulating film of a semiconductor substrate to form a plurality of wires of the same layer, a step of forming an organic resin film on the surface of the first insulating film selectively covered with the wires, a step of thinning the organic resin film to expose a surface of the wires, a step of depositing a sparse second insulating film on the entire surface, a step of removing the organic resin film, and a step of depositing a dense third insulating film. In the step of removing the organic resin film, O₂ plasma treatment is performed. In this step, by performing the O₂ plasma treatment, carbon in the second insulating film (organic SOG film) is removed and the second insulating film is changed into a sparse film. As a result, O₂ plasma passes through the second insulating film, and the organic resin film (resist film) can be removed (see paragraph [0023] of Patent Literature 1).

In addition, a method for manufacturing an electronic, photoelectronic, or electromechanical device, the method including: a) a step of disposing a sacrificial material layer on a device substrate; b) a step of disposing an overlay material on the sacrificial material layer; and c) a step of removing the sacrificial material layer in order to form an air gap, in which the sacrificial material layer contains a crosslinked polymer, has been proposed (see Patent Literature 2).

### CITATION LIST

### Patent Literature

Patent Literature 1: JP 09-172068 A
Patent Literature 2: JP 2004-266244 A

### SUMMARY OF INVENTION

### Technical Problem

In the technique of Patent Literature 1, in the O₂ plasma treatment for removing the organic resin film, it is necessary for the O₂ plasma to pass through the second insulating film, and therefore the material of the second insulating film is largely restricted. In addition, an apparatus for the O₂ plasma treatment is required.

Therefore, a method for removing the organic resin film by heating instead of the O₂ plasma treatment can be considered. In a case of heating, the restriction of the second insulating film is relatively small, and a heating apparatus can relatively suppress cost as compared with the O₂ plasma treatment apparatus.

In the technique of Patent Literature 2, a decomposition ratio by baking after film formation is not necessarily satisfactory.

The present invention has been made in view of the above circumstances, and an object thereof is to provide a cavity forming composition suitable for forming a cavity by heating between conductive wiring patterns on a semiconductor substrate, and a method for manufacturing a semiconductor element using the cavity forming composition.

### Solution to Problem

As a result of intensive studies to solve the above-described problems, the present inventors have found that the above-described problems can be solved by inclusion of a specific addition polymer in a cavity forming composition, and have completed the present invention.

That is, the present invention includes the following aspects.

[1] A cavity forming composition for forming a cavity between conductive wiring patterns on a semiconductor substrate, the cavity forming composition containing:
a solvent; and an addition polymer formed of two or more types of monomers having an ethylenically unsaturated bond, wherein
the addition polymer has a repeating unit (R1) having a thermosetting moiety and a repeating unit (R2) having an easily thermally decomposable moiety, and
a thermal decomposition temperature of the easily thermally decomposable moiety is higher than a thermally curing temperature of the thermosetting moiety.

[2] The cavity forming composition according to [1], wherein
a cured film obtained by heating a film formed of the cavity forming composition has a glass transition temperature of 86° C.; or higher, and
the cured film has a decomposition ratio of 95% or more when heated at 400° C.; for 30 minutes in a nitrogen atmosphere.

[3] The cavity forming composition according to claim [1] or [2], wherein the repeating unit (R1) contains a repeating unit represented by the following formula (R1-1):

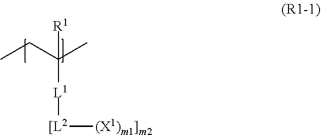

wherein in formula (R1-1), R¹ represents a hydrogen atom, a halogen atom, or an alkyl group;
L¹ and L² each independently represent a single bond or a linking group;
X¹ represents a group having at least one of an epoxy group, an oxetanyl group, a hydroxyalkyl group, an alkoxyalkyl group, a (meth)acryloyl group, a styryl group, and a vinyl group;
m1 represents an integer of 1 to 5, and when m1 is 2 or more, two or more X's may be the same or different; and
m2 represents an integer of 1 to 5, and when m2 is 2 or more, two or more [-L²-(X¹)ₘ₁] may be the same or different.

[4] The cavity forming composition according to [3], wherein the repeating unit (R1) further contains a repeating unit represented by the following formula (R1-2):

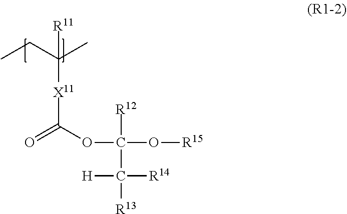

wherein in formula (R1-2), X¹¹ represents a single bond or a divalent organic group; R¹¹ represents a hydrogen atom, a halogen atom, or an alkyl group; R¹² to R¹⁴ each independently represent a hydrogen atom or an alkyl group having 1 to 10 carbon atoms; R¹⁵ represents an alkyl group having 1 to 10 carbon atoms; and R¹⁴ and R¹⁵ may be bonded to each other to form a ring.

[5] The cavity forming composition according to any one of [1] to [4], wherein the repeating unit (R2) contains a repeating unit represented by the following formula (R2-1):

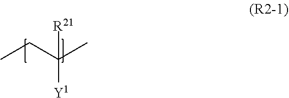

wherein in formula (R2-1), R²¹ represents a hydrogen atom or an alkyl group; and Y¹ represents a group represented by the following formula (R2-1-1), a phenyl group which may have a substituent, an alkyl group which may be halogenated, a monovalent alicyclic hydrocarbon group which may have a substituent, an alkylcarbonyloxy group which may be halogenated, an alkoxy group which may be halogenated, a nitrile group, or a halogen atom:

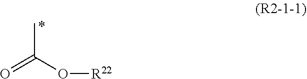

wherein in formula (R2-1-1), R²² represents a hydrocarbon group which may have a substituent of at least one of a halogen atom and a dialkylamino group; and * represents a bond.

[6] The cavity forming composition according to any one of [1] to [5], wherein the repeating unit (R1) in the addition polymer is 5 mol % to 50 mol % with respect to all repeating units of the addition polymer.

[7] The cavity forming composition according to any one of [1] to [6], wherein the repeating unit (R2) in the addition polymer is 50 mol % to 95 mol % with respect to all repeating units of the addition polymer.

[8]A method for manufacturing a semiconductor element, the method including:
a step (A) of applying the cavity forming composition according to any one of [1] to [7] onto a semiconductor substrate on which conductive wiring patterns are formed;
a step (B) of heating the semiconductor substrate to a temperature equal to or higher than a temperature at which the thermosetting moiety is thermally cured and lower than a temperature at which the easily thermally decomposable moiety is thermally decomposed after the step (A) to form a cavity forming curing material formed of the cavity forming composition between the conductive wiring patterns;
a step (C) of forming an insulating layer on the conductive wiring patterns and the cavity forming curing material between the conductive wiring patterns after the step (B); and
a step (D) of heating the semiconductor substrate to a temperature equal to or higher than a temperature at which the easily decomposable moiety is thermally decomposed after the step (C) to burn out the cavity forming curing material.

[9] The method for manufacturing a semiconductor element according to [8], wherein
in the step (B), the cavity forming curing material is formed also on the conductive wiring patterns, and
the method includes a step (E) of removing the cavity forming curing material on the conductive wiring patterns before the step (C).

[10] The method for manufacturing a semiconductor element according to [8], the method including a step (F) of removing an uncured cavity forming material which is present on the conductive wiring patterns and is formed of the cavity forming composition between the step (A) and the step (B).

[11] The method for manufacturing a semiconductor element according to any one of [8] to [10], wherein in the step (C), the insulating layer is formed by chemical vapor deposition.

### Advantageous Effects of Invention

According to the present invention, it is possible to provide a cavity forming composition suitable for forming a cavity by heating between conductive wiring patterns on a semiconductor substrate, and a method for manufacturing a semiconductor element using the cavity forming composition.

### BRIEF DESCRIPTION OF DRAWINGS

FIG. 1A is a schematic cross-sectional view for explaining an example of a method for manufacturing a semiconductor element (part 1).

FIG. 1B is a schematic cross-sectional view for explaining the example of the method for manufacturing a semiconductor element (part 2).

FIG. 1C is a schematic cross-sectional view for explaining the example of the method for manufacturing a semiconductor element (part 3).

FIG. 1D is a schematic cross-sectional view for explaining the example of the method for manufacturing a semiconductor element (part 4).

FIG. 1E is a schematic cross-sectional view for explaining the example of the method for manufacturing a semiconductor element (part 5).

FIG. 1F is a schematic cross-sectional view for explaining the example of the method for manufacturing a semiconductor element (part 6).

### DESCRIPTION OF EMBODIMENTS

### (Cavity Forming Composition)

A cavity forming composition of the present invention is a composition for forming a cavity between conductive wiring patterns on a semiconductor substrate.

The cavity forming composition contains an addition polymer and a solvent.

### <Addition Polymer>

The addition polymer is an addition polymer formed of two or more types of monomers having an ethylenically unsaturated bond (hereinafter, also referred to as a “monomer”).

The addition polymer is obtained by addition polymerization of two or more types of monomers.

Note that the ethylenically unsaturated bond means a radically polymerizable carbon-carbon double bond.

A preferable embodiment of the addition polymer has a repeating unit (R1) having a thermosetting moiety and a repeating unit (R2) having an easily thermally decomposable moiety.

A thermal decomposition temperature of the easily thermally decomposable moiety is higher than a thermally curing temperature of the thermosetting moiety.

A preferable embodiment of the addition polymer contains a repeating unit represented by formula (R1-1) described later and a repeating unit represented by formula (R2-1) described later.

In order to improve film curability of a film obtained from the cavity forming composition, the cavity forming composition may contain a crosslinking agent that reacts with a crosslinkable moiety in the addition polymer. However, in a preferable embodiment, an addition amount of the crosslinking agent with respect to the amount of the addition polymer is preferably 0% by mass to 10% by mass, and more preferably 0% by mass to 5% by mass from a viewpoint of a decomposition ratio.

In addition, in order to improve film curability of a film obtained from the cavity forming composition, the addition polymer may have a crosslinked structure. However, a preferable embodiment is a low-crosslinked or non-crosslinked addition polymer from a viewpoint of a decomposition ratio. In an addition polymer in one aspect, a mass ratio of the two or more monomers having an ethylenically unsaturated bond in constituent components is preferably 0% by mass to 10% by mass, and more preferably 0% by mass to 5% by mass.

The cavity forming composition is suitably used for manufacturing a semiconductor element, including the following steps (A) to (D).
Step (A): a step of applying the cavity forming composition onto a semiconductor substrate on which conductive wiring patterns are formed
Step (B): a step of heating the semiconductor substrate to a temperature equal to or higher than a temperature at which the thermosetting moiety is thermally cured and lower than a temperature at which the easily thermally decomposable moiety is thermally decomposed after the step (A) to form a cavity forming curing material (cured cavity forming material) formed of the cavity forming composition between the conductive wiring patterns
Step (C): a step of forming an insulating layer on the conductive wiring patterns and the cavity forming curing material between the conductive wiring patterns after the step (B)
Step (D): a step of heating the semiconductor substrate to a temperature equal to or higher than a temperature at which the easily decomposable moiety is thermally decomposed after the step (C) to burn out the cavity forming curing material

Since the addition polymer contained in the cavity forming composition of the present invention has the repeating unit (R1) having a thermosetting moiety, the cavity forming curing material (cured cavity forming material) formed in the step (B) is less likely to be softened by heat as compared with a non-cured cavity forming material. Here, when the cavity forming material is softened and deformed by application of heat to the cavity forming material during formation of the insulating layer in the step (C), a uniform insulating layer is hardly formed. However, since the cavity forming curing material is hardly softened, a uniform insulating layer can be formed.

In addition, the addition polymer contained in the cavity forming composition of the present invention has the repeating unit (R2) having an easily thermally decomposable moiety. Therefore, when the cavity forming curing material is burned out in the step (D), the addition polymer contained in the cavity forming composition of the present invention can burn out the cavity forming curing material at a higher decomposition ratio as compared with an addition polymer having no repeating unit (R2) having an easily thermally decomposable moiety.

Therefore, the cavity forming composition of the present invention is suitable for forming a cavity by heating between conductive wiring patterns on a semiconductor substrate.

In a preferable embodiment of the cavity forming composition of the present invention, a cured film obtained by heating a film formed of the cavity forming composition has a glass transition temperature of 86° C.; or higher. As the glass transition temperature is higher, a more uniform insulating layer can be formed. The glass transition temperature is more preferably 90° C.; or higher, and particularly preferably 93° C.; or higher. An upper limit value of the glass transition temperature is not particularly limited, but for example, the glass transition temperature may be 130° C.; or lower, or 120° C.; or lower.

The glass transition temperature can be measured, for example, by the following method.

The cavity forming composition is applied by spin coating to prepare a coating film on a silicon substrate at a predetermined baking temperature (for example, 205° C.; or 215° C.). The coating film has a film thickness of 40 nm to 50 nm. Then, the coating film is scraped, and the obtained powder is subjected to differential scanning calorimetry.

For the measurement, differential scanning calorimetry (DSC) is used. First, the temperature is raised to 140° C. to erase a thermal history. Thereafter, the temperature is lowered to 0° C.; at a temperature lowering rate of 20° C./min, and measurement is performed again at a temperature rising rate of 20° C./min. A temperature indicating an inflection point of a transition region appearing stepwise in a thermogram at this time is defined as the glass transition temperature. Note that, for a result that no inflection point is observed, the glass transition temperature is defined as 100° C.; or higher. An apparatus used is Q2000 manufactured by TA Instruments, and a sample amount is about 5 mg.

The baking temperature may be, for example, the heating temperature in the step (B).

In addition, in a preferable embodiment of the cavity forming composition of the present invention, when a cured film obtained by heating a film formed of the cavity forming composition is heated at 400° C.; for 30 minutes under a nitrogen atmosphere, a decomposition ratio is 95% or more. As the decomposition ratio is larger, a dielectric constant of a cavity (for example, a cavity formed in the step (D)) to be formed can be lower. The decomposition ratio is preferably 96% or more, more preferably 97% or more, and particularly preferably 98% or more.

The decomposition ratio can be measured, for example, by the following method.

The cavity forming composition is applied by spin coating to prepare a coating film on a silicon substrate at a predetermined baking temperature (for example, 205° C.; or 215° C.). The coating film has a film thickness of 40 nm to 50 nm. The baking temperature may be, for example, the heating temperature in the step (B).

The thickness of the coating film is measured using VM-3210 (manufactured by SCREEN Semiconductor Solutions Co., Ltd.). Thereafter, the silicon substrate to which the cavity forming composition has been applied is heated for 30 minutes with a plate preheated to 400° C.; under a nitrogen atmosphere. Finally, the film thickness of the resulting coating film on the substrate is measured again using RE-3100 and RE-3500 (manufactured by SCREEN Semiconductor Solutions Co., Ltd.). From the obtained results, a thermal decomposition ratio of the coating film is calculated using the following formula 1.

$$( Decomposition ratio [ \% ] ) = 100 \times ( 1 - {T}_{1} / {T}_{0} ) \qquad Formula 1$$

T₀=film thickness of coating film before firing decomposition
T₁=film thickness of coating film after firing decomposition

### <<Repeating Unit (R1)>>

The repeating unit (R1) of the addition polymer is not particularly limited as long as it has a thermosetting moiety. The thermosetting moiety may be a moiety in which the same type of thermosetting moieties react with each other (for example, an epoxy group or a hydroxyalkyl group), or may be a moiety in which different types of thermosetting moieties react with each other (for example, a combination of an epoxy group and a carboxyl group.). In addition, the thermosetting moiety may be a moiety that reacts by heating in the presence of a catalyst or a moiety that reacts by heating in the absence of a catalyst. In addition, the thermosetting moiety may be a moiety having a structure (for example, a hemiacetal ester structure) in which an elimination component is eliminated by heating to generate a reactive group.

### <<<Formula (R1-1)>>>

The repeating unit (R1) preferably contains a repeating unit represented by the following formula (R1-1) from a viewpoint of suitably obtaining the effect of the present invention:

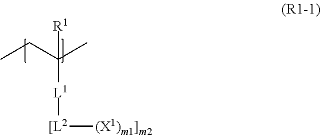

(In formula (R1-1), R¹ represents a hydrogen atom, a halogen atom, or an alkyl group;
L¹ and L² each independently represent a single bond or a linking group;
X¹ represents a group having at least one of an epoxy group, an oxetanyl group, a hydroxyalkyl group, an alkoxyalkyl group, a (meth)acryloyl group, a styryl group, and a vinyl group;
m1 represents an integer of 1 to 5, and when m1 is 2 or more, two or more X's may be the same or different; and
m2 represents an integer of 1 to 5, and when m2 is 2 or more, two or more [-L²-(X¹)ₘ₁] may be the same or different.).

In the present specification, examples of the halogen atom include a fluorine atom, a chlorine atom, a bromine atom, and an iodine atom.

The alkyl group of R¹ is not particularly limited, but is preferably an alkyl group having 1 to 6 carbon atoms, more preferably an alkyl group having 1 to 4 carbon atoms, still more preferably a methyl group or an ethyl group, and particularly preferably a methyl group.

The repeating unit represented by formula (R1-1) preferably contains no aromatic ring from a viewpoint of exhibiting favorable thermal decomposability during heating.

-L¹-

L¹ is a single bond or a linking group, preferably a linking group, and more preferably a divalent linking group.

The linking group is not particularly limited, but preferable examples thereof include a carbonyl group, a thiocarbonyl group, an alkylene group (preferably having 1 to 10 carbon atoms, more preferably having 1 to 5 carbon atoms), an aromatic ring group, an aliphatic ring group, an —O— group, a sulfonyl group, an —NH— group, and a group obtained by combining these groups (preferably having 1 to 20 carbon atoms in total, more preferably having 1 to 10 carbon atoms in total).

The aromatic ring group may be an aromatic hydrocarbon ring group or an aromatic heterocyclic group. In addition, the aromatic ring group may be a monocyclic ring or a polycyclic ring, and the polycyclic ring may be a fused ring. An aromatic hydrocarbon ring group and an aromatic ring heterocyclic group are preferable, and an aromatic hydrocarbon ring group is more preferable.

As the aromatic hydrocarbon ring group, a benzene ring group, a naphthalene ring group, and an anthracene ring group are preferable, and a benzene ring group is particularly preferable. Examples of the aromatic ring heterocyclic group include a thiophene ring group, a furan ring group, a pyrrole ring group, a triazine ring group, an imidazole ring group, a triazole ring group, a thiadiazole ring group, and a thiazole ring group.

The aliphatic cyclic group may be an aliphatic hydrocarbon cyclic group or an aliphatic heterocyclic group. In addition, the aliphatic cyclic group may be a monocyclic ring or a polycyclic ring, and the polycyclic ring may be a fused ring. Examples of the aliphatic hydrocarbon ring group include a cyclohexane group.

When the linking group L¹ is a “combined group”, a group containing —C(═O)—O—, a group containing an aromatic ring group, a group containing —C(═O)—NH—, and the like are preferable.

In the present invention, a “group containing XXX” also includes a group consisting only of XXX.

The linking group L¹ is particularly preferably a —C(═O)—O— group or a benzene ring.

-L²-

L² is a single bond or a linking group. When L² is a linking group, the linking group is preferably divalent. Here, at least one of L¹ and L² is preferably a linking group.

The linking group L² is not particularly limited and is synonymous with the linking group L¹, but the linking group L² is preferably the following group or a combined group. That is, examples of the preferable group include an alkylene group, an aliphatic ring group, and an aromatic ring group. Here, the alkylene group preferably has 1 to 4 carbon atoms, and is particularly preferably methylene.

On the other hand, preferable examples of the “combined group” include an —O-alkylene group, an alkylene group-O—, an —O—C(═O)— group, an —O—C(═O)—NH-alkylene group, an —O-alkylene group-C(═O)—O-aromatic ring group, an alkylene group-O—, an -alkylene group-O-aromatic ring group, an -alkylene group-C(═O)—O-alkylene group, and an -alkylene group-O—C(═O)-alkylene group-C(═O)—O-alkylene group, and the combined group is more preferably a group containing an —O— group bonded to L¹. Here, the alkylene group in the combined group preferably has 1 to 4 carbon atoms, and is particularly preferably a methylene group or an ethylene group.

Among these groups, L² is preferably an alkylene group or an —O-alkylene group.

In particular, when L¹ is a —C(═O)—O— group, L² is preferably an alkylene group, and when L¹ is an aromatic ring group, L² is preferably an —O-alkylene group.

—X¹—

X¹ has at least one of an epoxy group, an oxetanyl group, a hydroxyalkyl group, an alkoxyalkyl group, a (meth)acryloyl group, a styryl group, and a vinyl group.

The epoxy group, oxetanyl group, hydroxyalkyl group, alkoxyalkyl group, (meth)acryloyl group, styryl group, and vinyl group in X¹ react (are cured) by heating in the presence or absence of a curing catalyst, and as a result, the addition polymer forms a crosslinked structure.

In X¹, examples of a group having an epoxy group include a group represented by the following formula (Ox-1) and a group represented by the following formula (Ox-2).

In X¹, examples of a group having an oxetanyl group include a group represented by the following formula (Ox-3).

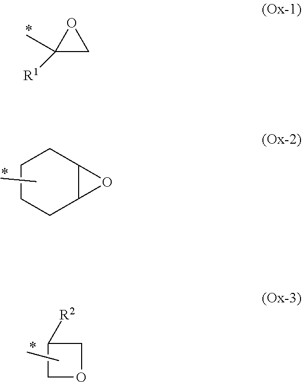

(In formulas (Ox-1) to (Ox-3), * represents a bond. R¹ and R each independently represent a hydrogen atom, a methyl group, or an ethyl group.)

Examples of the group represented by formula (Ox-2) include a group represented by the following formula (Ox-2-1).

Examples of the group represented by formula (Ox-3) include a group represented by the following formula (Ox-3-1).

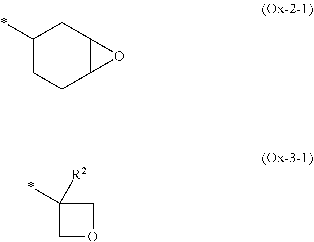

(In formulas (Ox-2-1) and (Ox-3-1), * represents a bond. R² represents a hydrogen atom, a methyl group, or an ethyl group.)

Examples of the group having a hydroxyalkyl group in X¹ include a hydroxyalkyl group.

The hydroxyalkyl group may have one hydroxy group, two hydroxy groups, or three or more hydroxy groups.

The number of carbon atoms of the hydroxyalkyl group is, for example, 1 to 10.

The hydroxyalkyl group may have a substituent. Examples of the substituent include a halogen atom, an alkoxy group, and an acyloxy group. Examples of the alkoxy group include an alkoxy group having 1 to 4 carbon atoms. Examples of the acyloxy group include an acyloxy group having 2 to 4 carbon atoms. Examples of the acyloxy group include a monovalent group obtained by removing a hydrogen atom in —COOH from RCOOH (R represents an alkyl group.).

Examples of the hydroxyalkyl group include a hydroxymethyl group, a 2-hydroxyethyl group, and a 3-hydroxypropyl group.

Examples of the group having an alkoxyalkyl group in X¹ include an alkoxyalkyl group.

The alkoxyalkyl group may have one alkoxy group, two alkoxy groups, or three or more alkoxy groups.

The number of carbon atoms of the alkoxyalkyl group is, for example, 2 to 15.

The alkoxyalkyl group may have a substituent. Examples of the substituent include a halogen atom and an acyloxy group. Examples of the acyloxy group include an acyloxy group having 2 to 4 carbon atoms. Examples of the acyloxy group include a monovalent group obtained by removing a hydrogen atom in —COOH from RCOOH (R represents an alkyl group.).

The alkyl group in the hydroxyalkyl group and the alkoxyalkyl group may be linear, branched, cyclic, or a combination of two or more thereof.

Examples of the group having a (meth)acryloyl group in X¹ include an acryloyloxy group and a methacryloyloxy group.

m1 is an integer of 1 to 5, preferably an integer of 1 to 3, and more preferably 1 or 2. In particular, when X¹ is a group having an epoxy group or an oxetanyl group, m1 is preferably 1, and when X¹ is a group other than a group having an epoxy group or an oxetanyl group, m1 is preferably 2 or 3.

m2 is an integer of 1 to 5, preferably an integer of 1 to 4, and more preferably 1 or 2.

The repeating unit represented by formula (R1-1) is preferably a repeating unit represented by the following formula (R1-1-1).

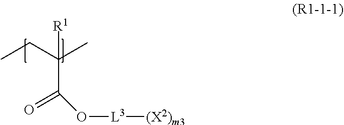

In formula (R1-1-1), R¹ represents a hydrogen atom, a halogen atom, or an alkyl group, and is synonymous with R¹ in formula (R1-1).

L³ represents a single bond or a linking group. L³ is preferably a linking group, more preferably an alkylene group, an -alkylene group-O-aromatic ring group, an -alkylene group-C(═O)—O-alkylene group, an -alkylene group-O—C(═O)-alkylene group-C(═O)—O-alkylene group, or the like, and still more preferably an alkylene group. Here, each of the alkylene group and the alkylene group in a group obtained by combining the alkylene group with another group preferably has 1 to 4 carbon atom, and is particularly preferably a methylene group or an ethylene group.

X² is synonymous with X¹ in formula (R1-1).

m3 represents an integer of 1 to 5 and is synonymous with m2 in formula (R1-1). Preferable ones for m3 are also the same as those for m2.

Formulas (R1-1) and (R1-1-1) when X¹ or X² is a group having an epoxy group or an oxetanyl group will be specifically described.

Examples of a monomer that gives the repeating unit (R1-1) having an epoxy group to the addition polymer include glycidyl acrylate, glycidyl methacrylate, glycidyl α-ethylacrylate, glycidyl α-n-propylacrylate, glycidyl α-n-butylacrylate, 3,4-epoxybutyl acrylate, 3,4-epoxybutyl methacrylate, 3,4-epoxycyclohexylmethyl acrylate, 3,4-epoxycyclohexylmethyl methacrylate, 3,4-epoxycyclohexylmethyl α-ethylacrylate, o-vinylbenzylglycidyl ether, m-vinylbenzylglycidyl ether, p-vinylbenzylglycidyl ether, and compounds containing an alicyclic epoxy skeleton described in paragraphs [0031] to [0035] of JP 4168443 B2. Contents thereof are incorporated herein.

In addition, examples of a monomer that gives the repeating unit (R1-1) having an oxetanyl group to the addition polymer include a (meth)acrylate having an oxetanyl group described in paragraphs [0011] to [0016] of JP 2001-330953 A and compounds described in paragraph [0027] of JP 2012 088459 A. Contents thereof are incorporated herein.

Furthermore, a monomer that gives the repeating unit (R1-1) having an epoxy group and an oxetanyl group to the addition polymer is preferably, for example, a monomer containing a methacrylate structure or a monomer containing an acrylate structure.

Among these monomers, glycidyl methacrylate, 3,4-epoxycyclohexylmethyl acrylate, 3,4-epoxycyclohexylmethyl methacrylate, o-vinylbenzyl glycidyl ether, m-vinylbenzyl glycidyl ether, p-vinylbenzyl glycidyl ether, (3-ethyloxetan-3-yl) methyl acrylate, and (3-ethyloxetan-3-yl) methyl methacrylate are preferable from a viewpoint of improving reactivity and various properties of a cured film. These constituent units can be used singly or in combination of two or more types thereof.

Preferable examples of the repeating unit represented by formula (R1-1) are the following repeating units.

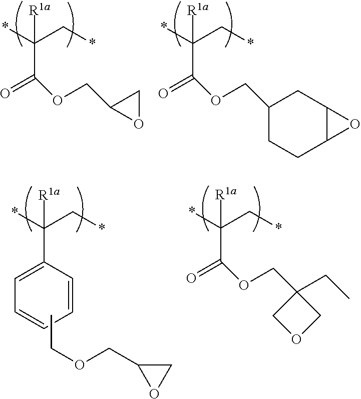

(in which R^{1a} is synonymous with R¹ in formula (R1-1). * represents a bond.)

Specific examples of the repeating unit represented by formula (R1-1) are presented below. Hereinafter, Me represents a methyl group. * represents a bond.

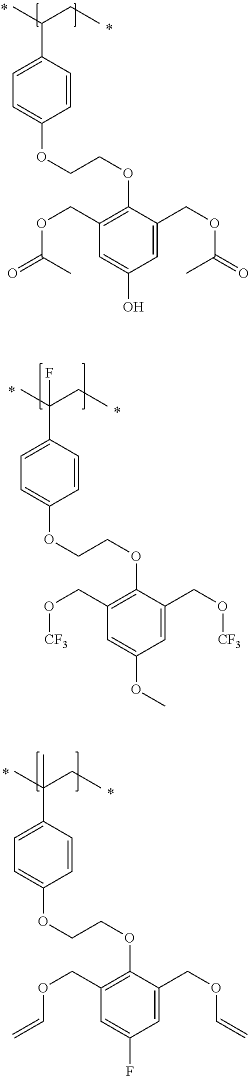

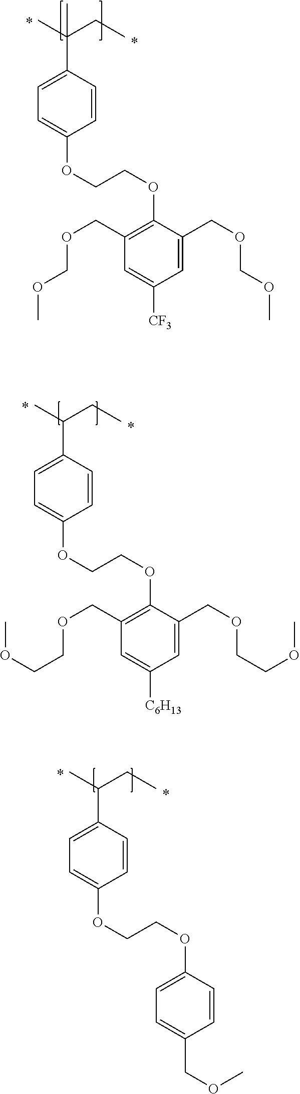

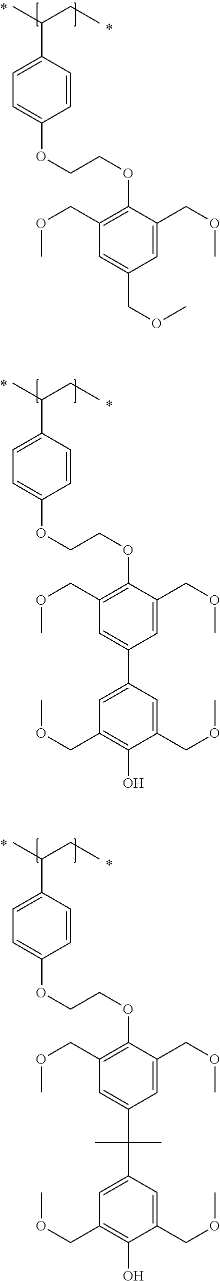

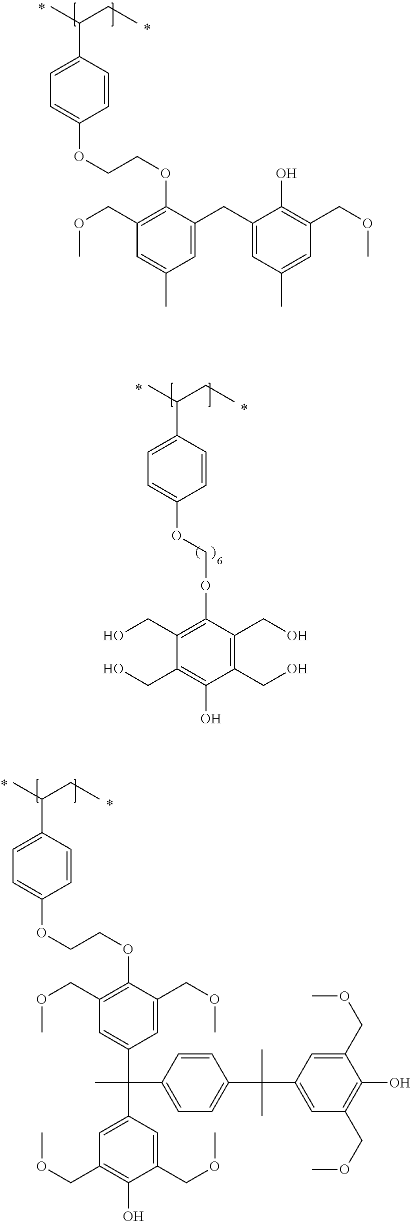

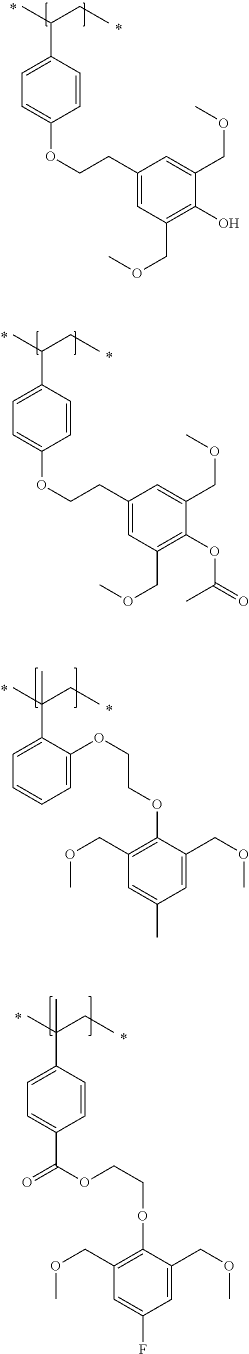

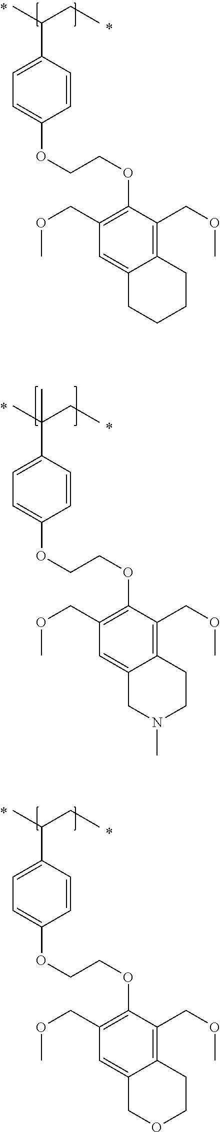

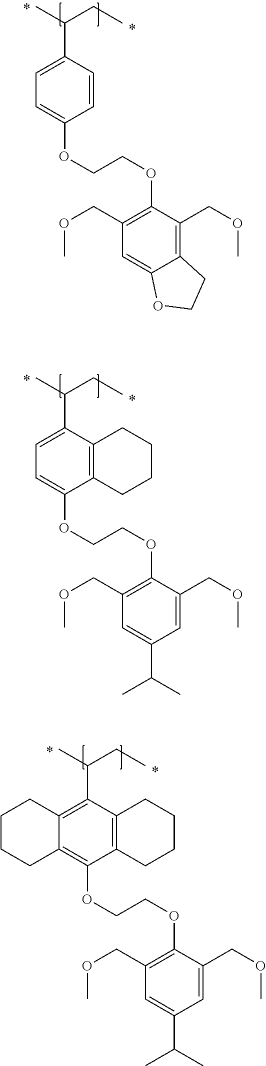

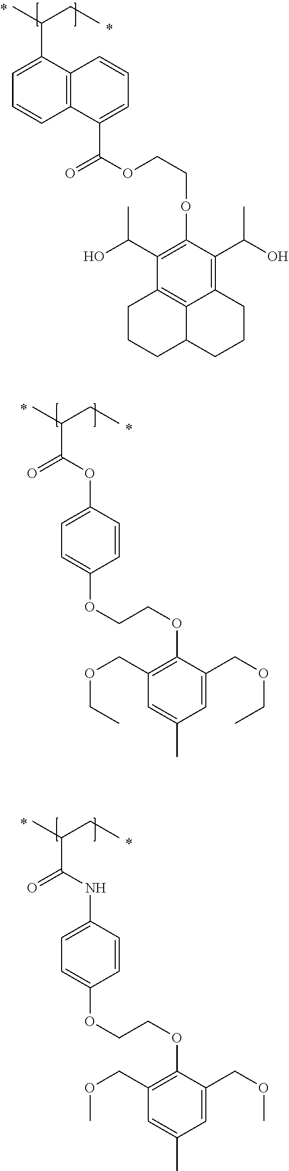

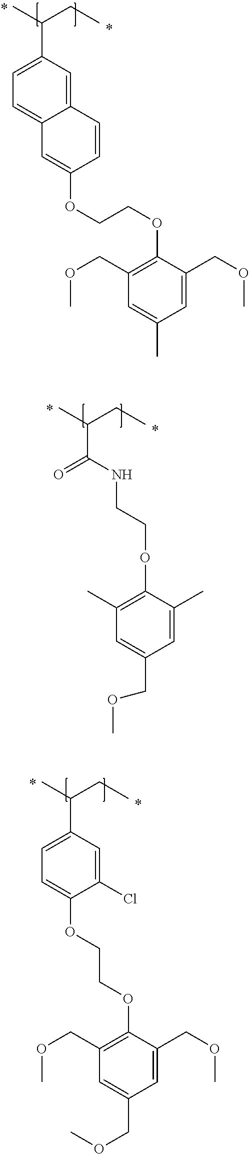

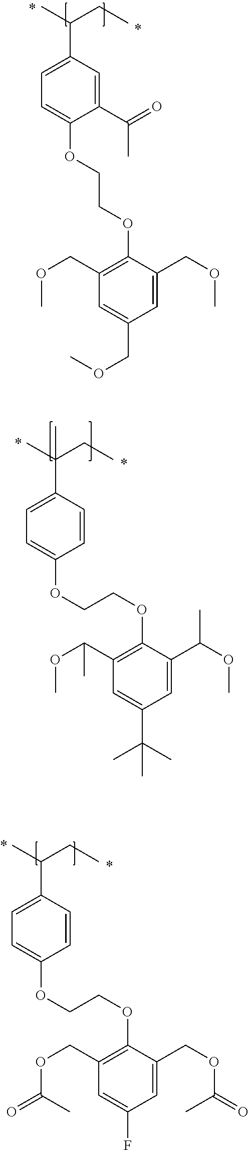

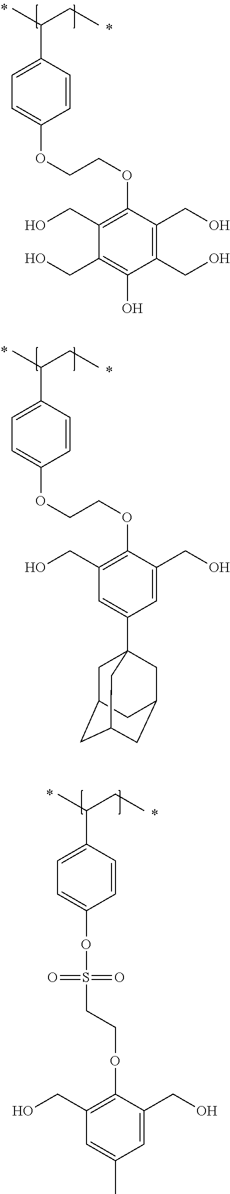

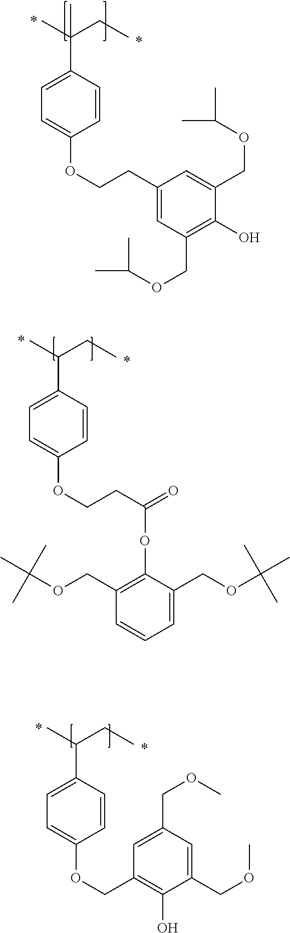

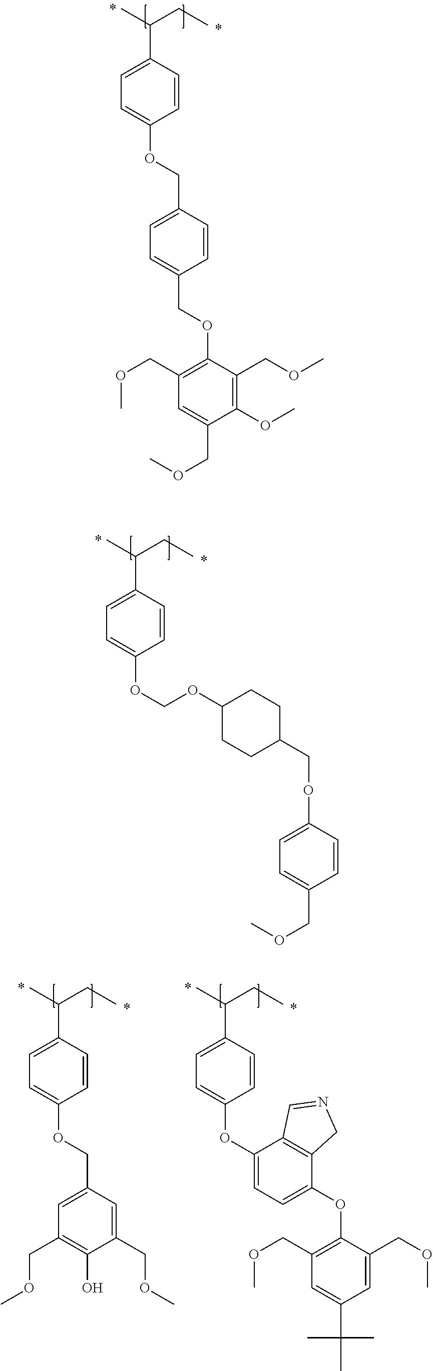

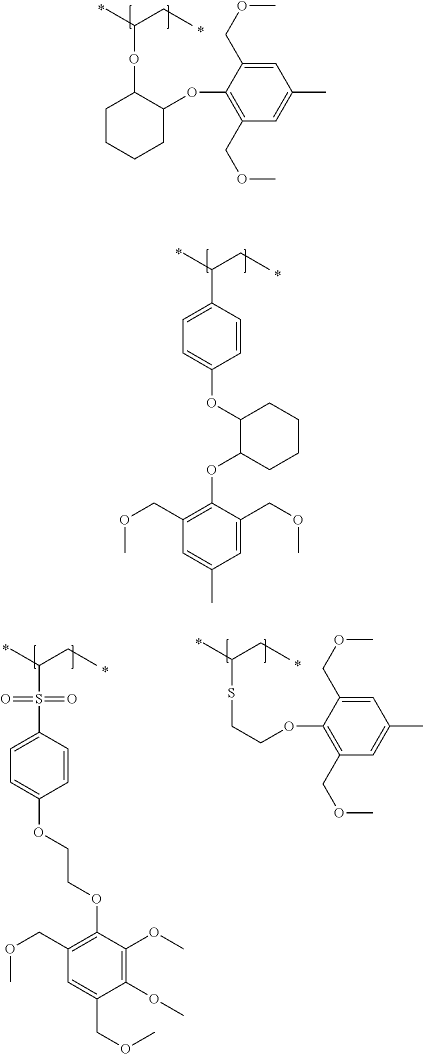

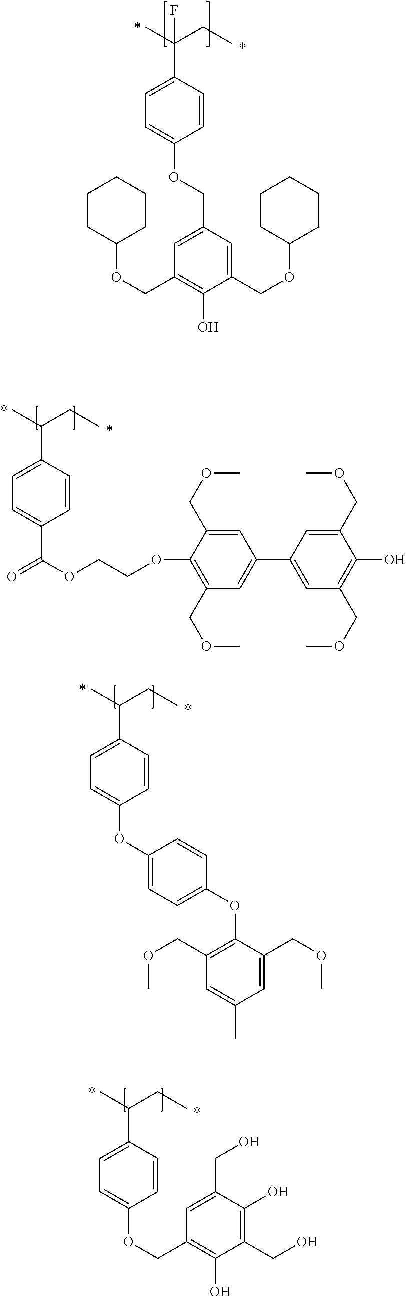

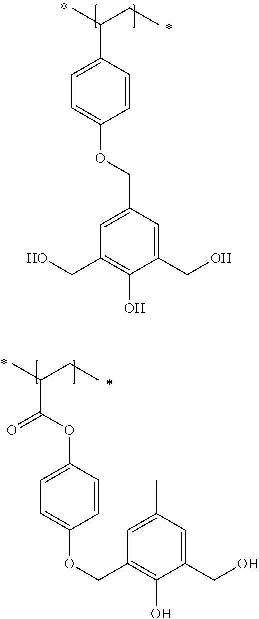

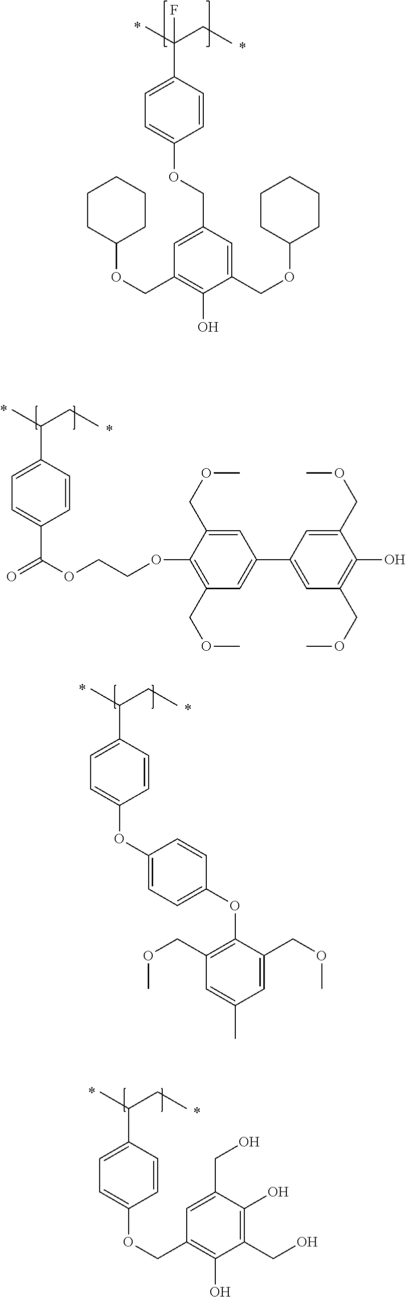

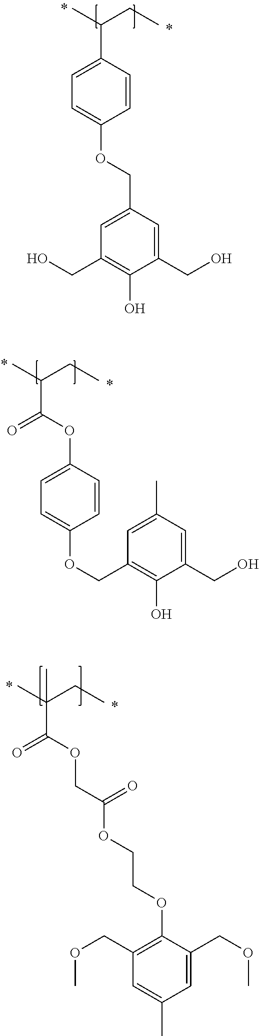

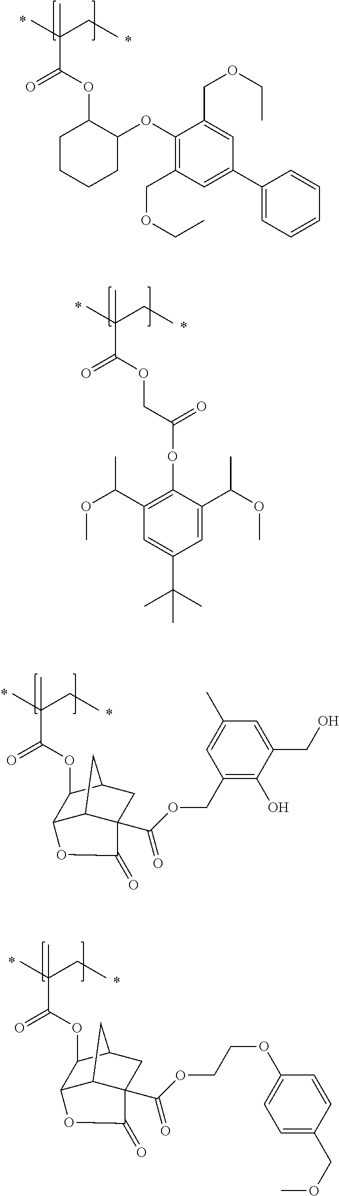

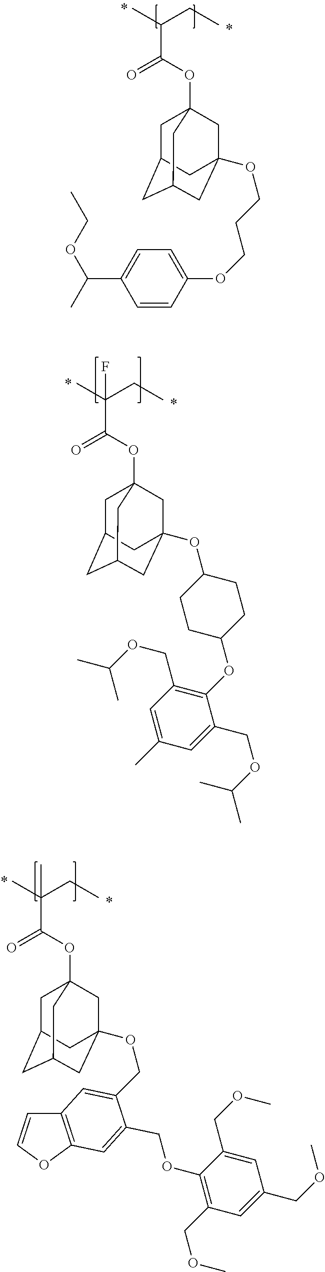

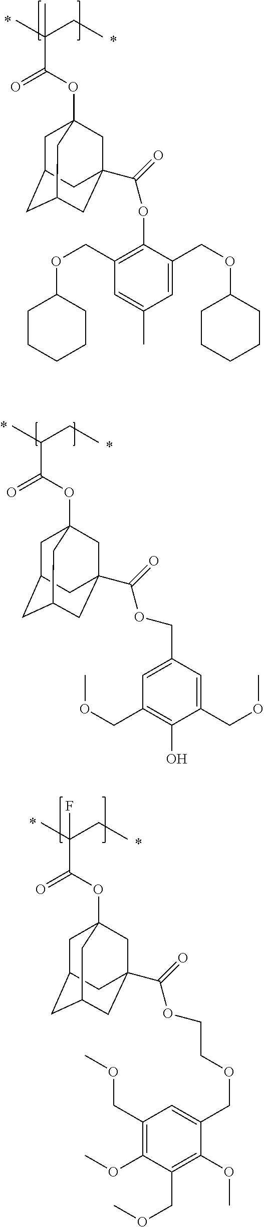

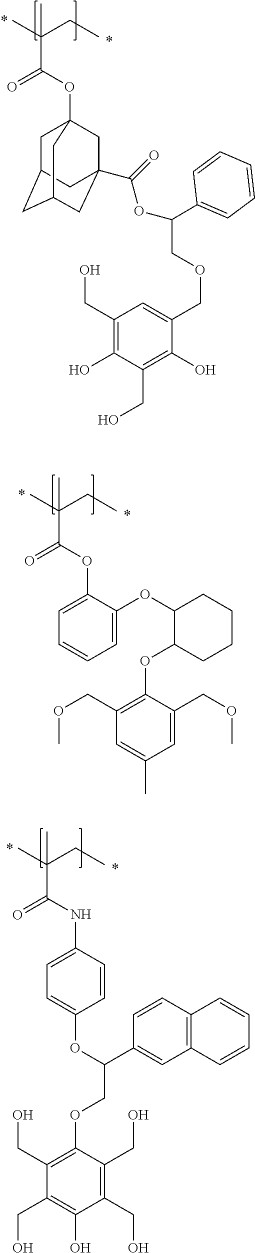

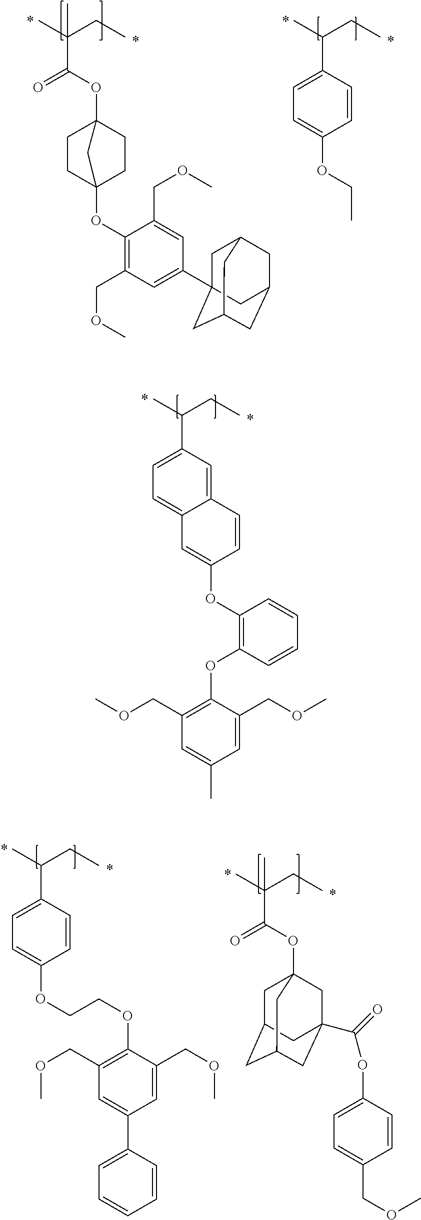

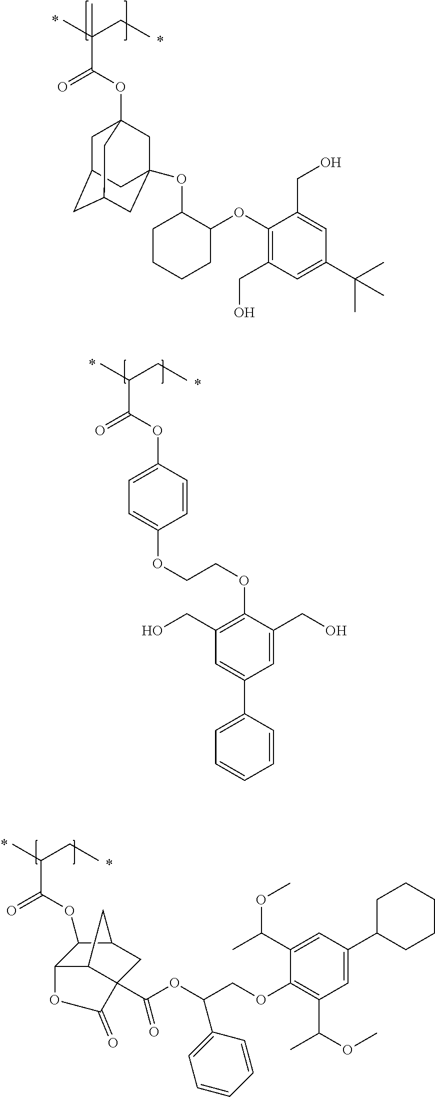

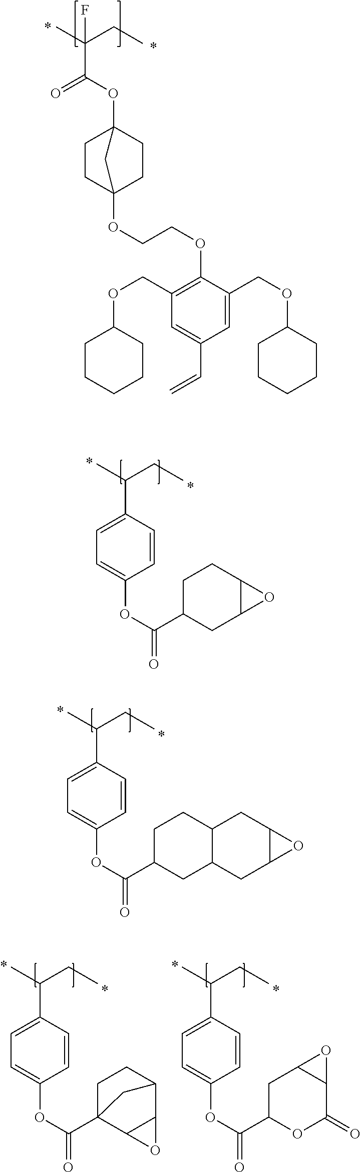

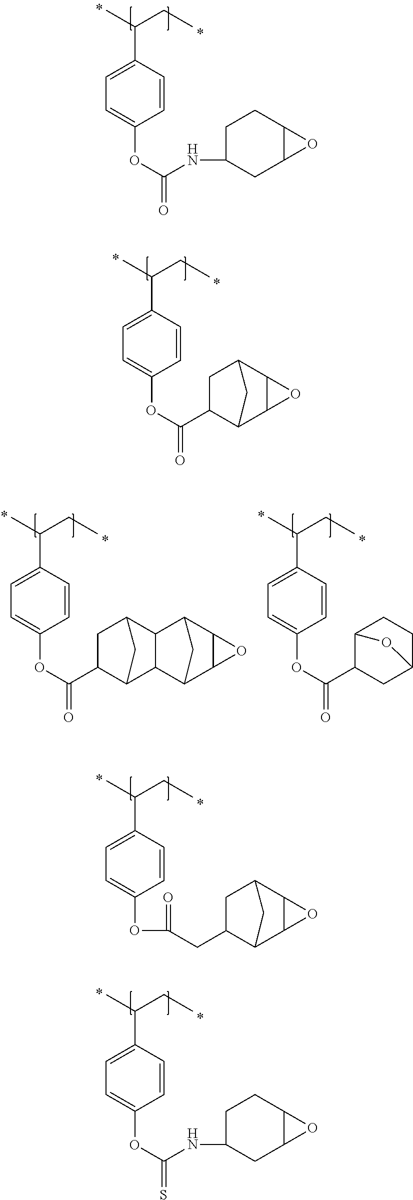

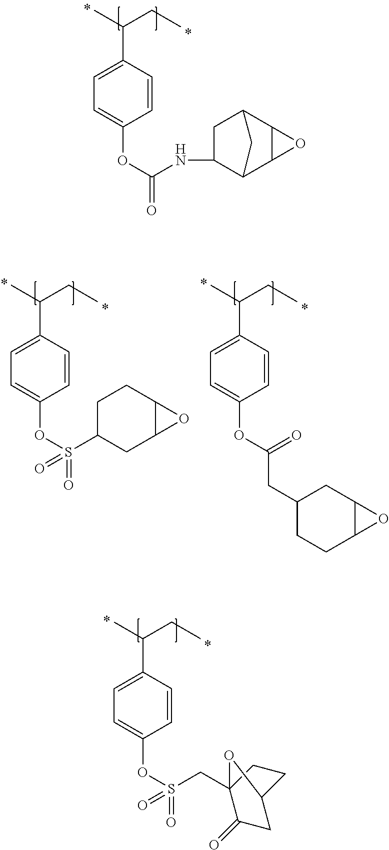

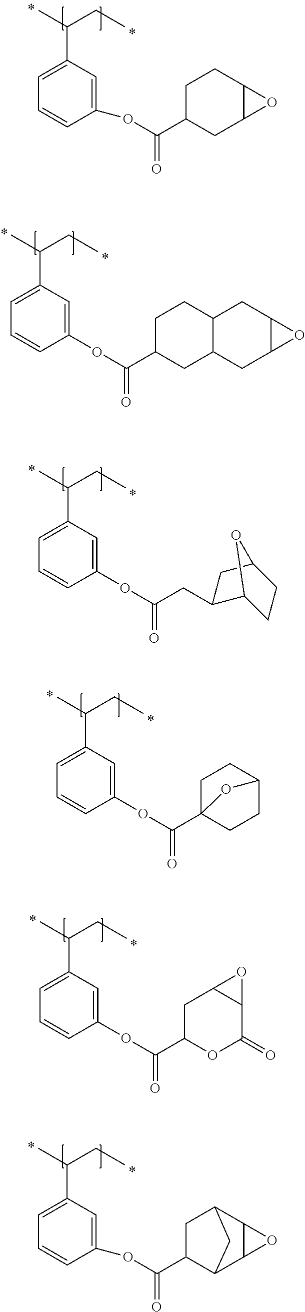

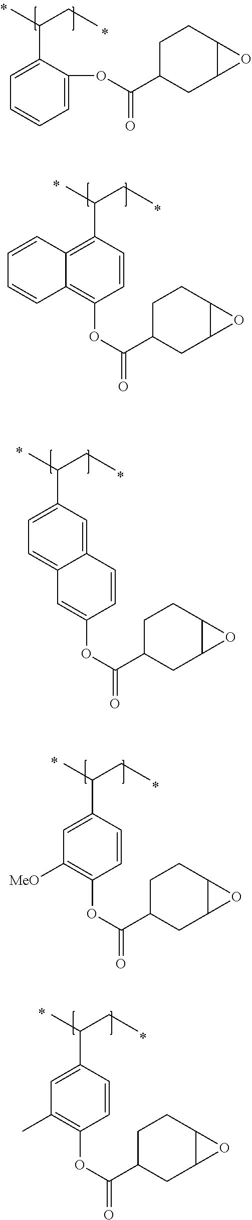

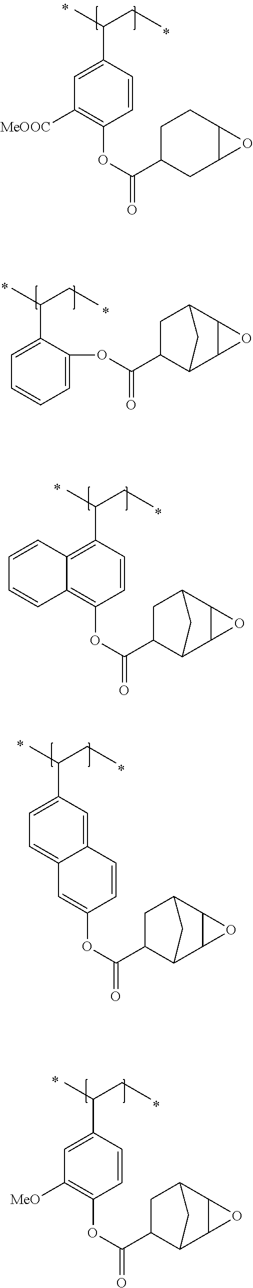

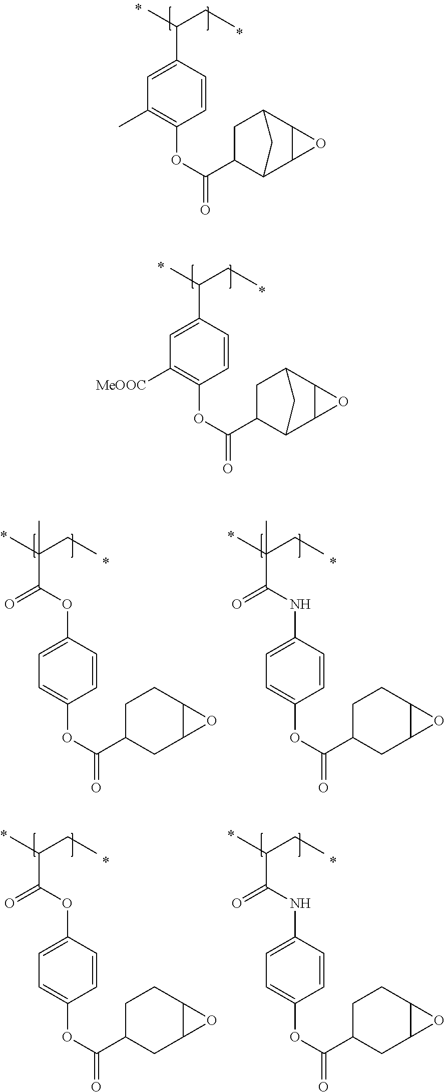

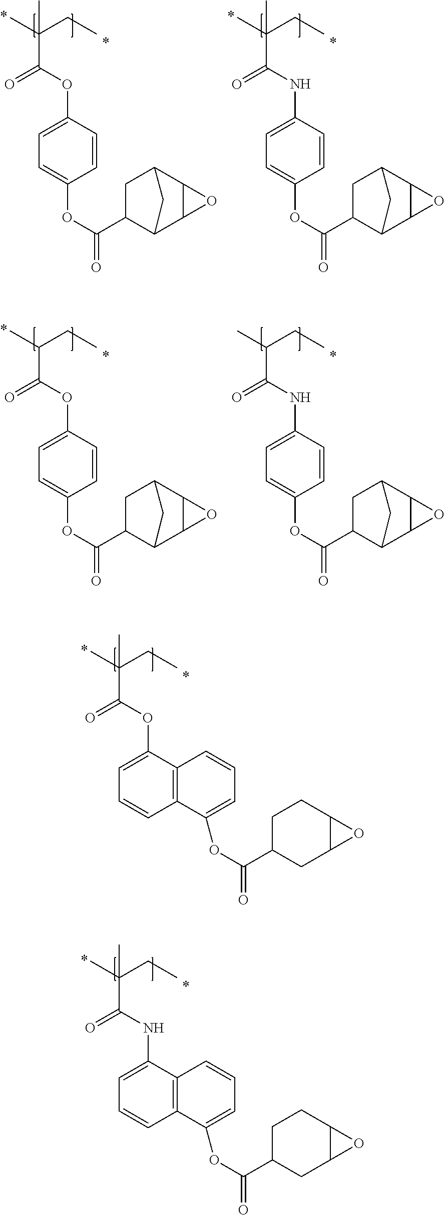

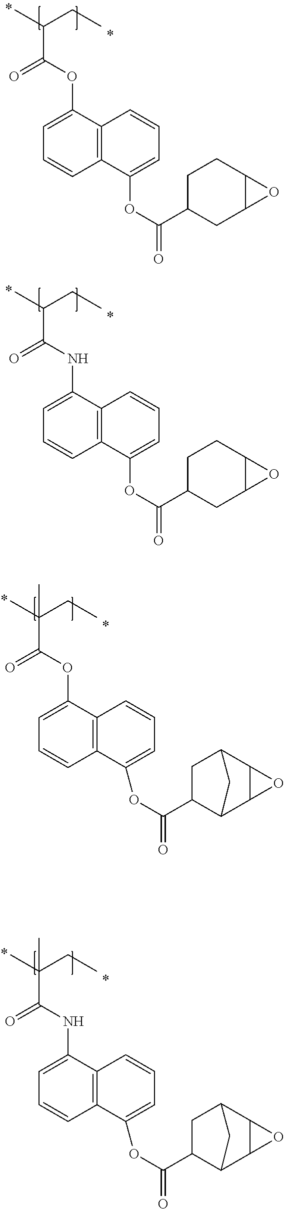

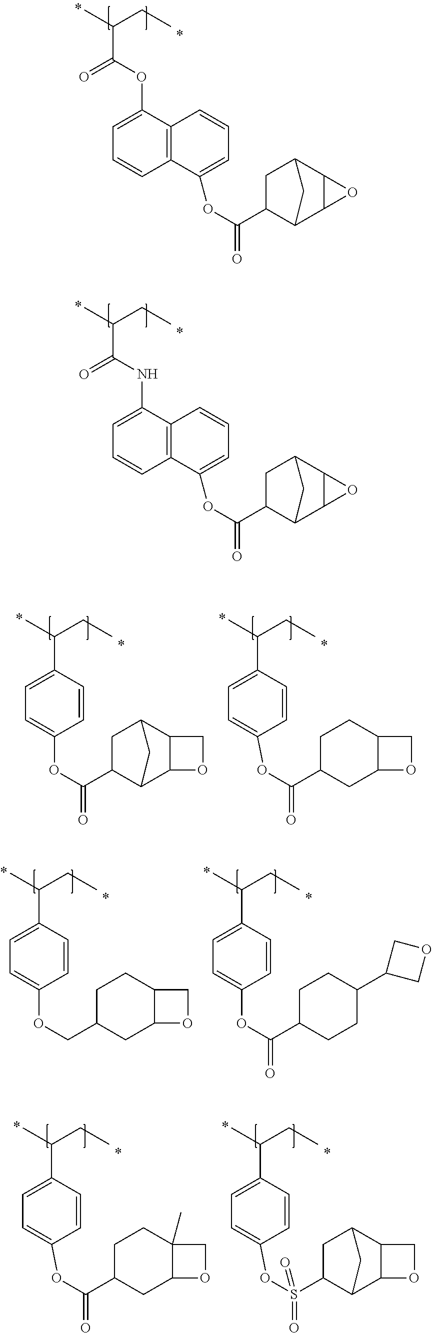

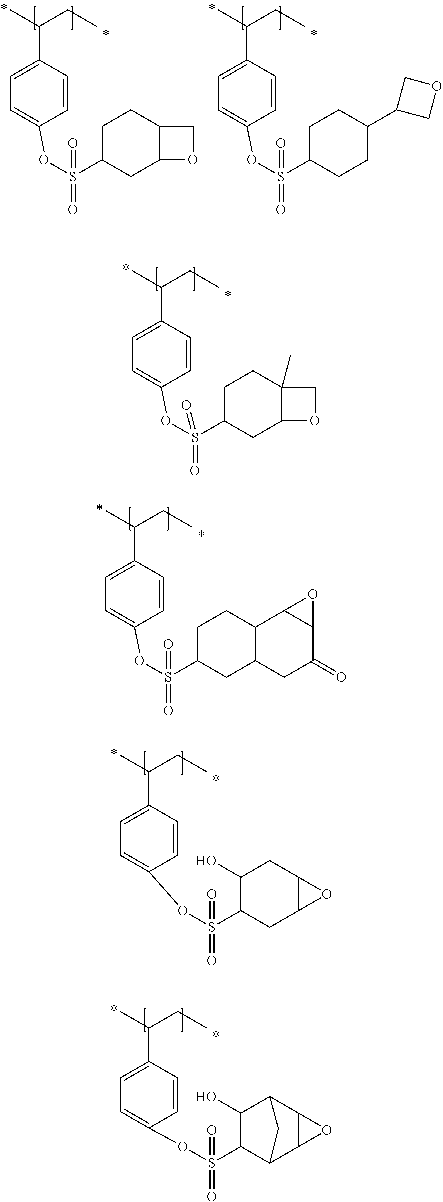

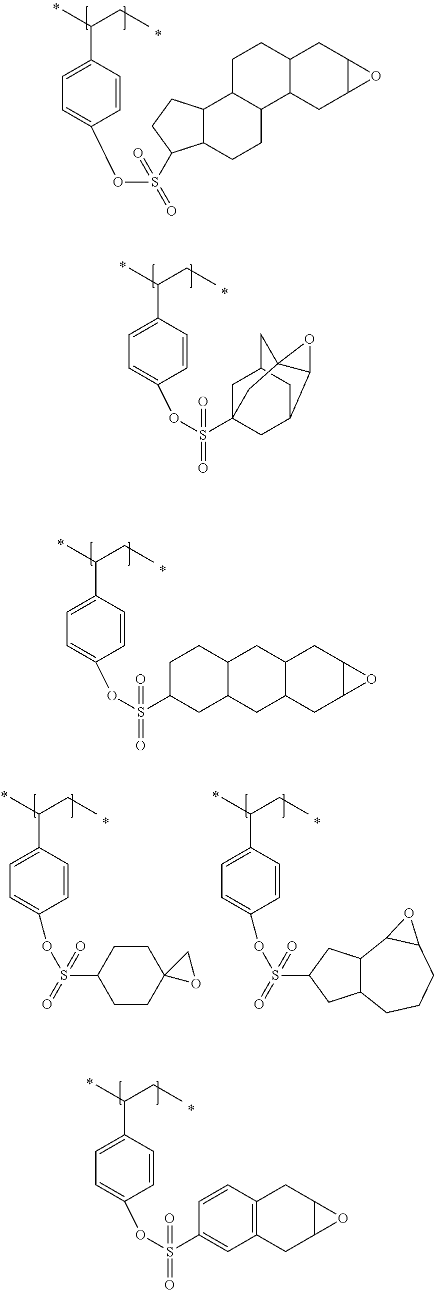

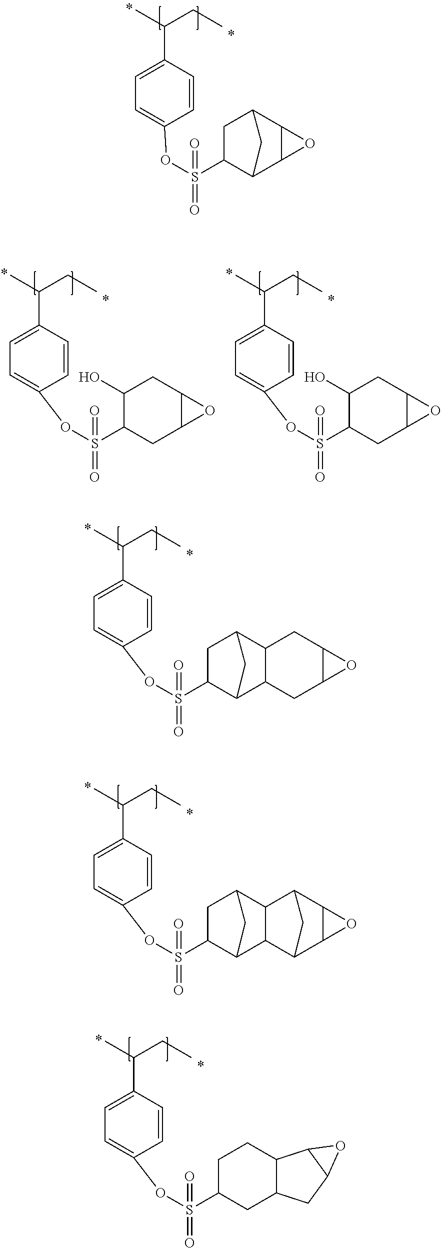

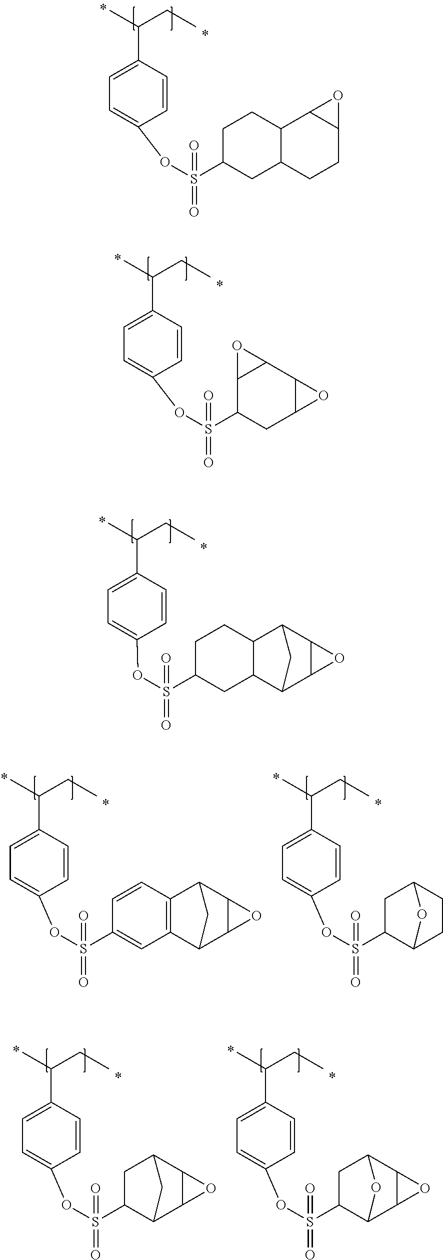

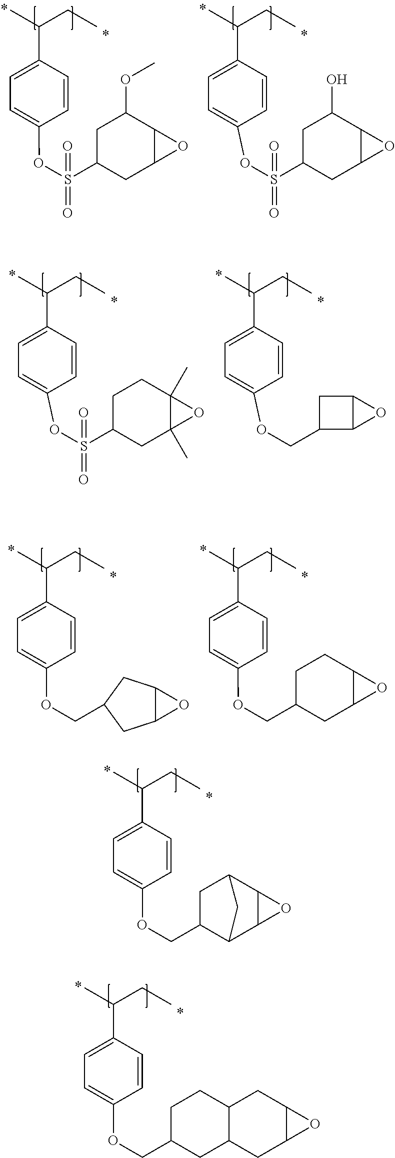

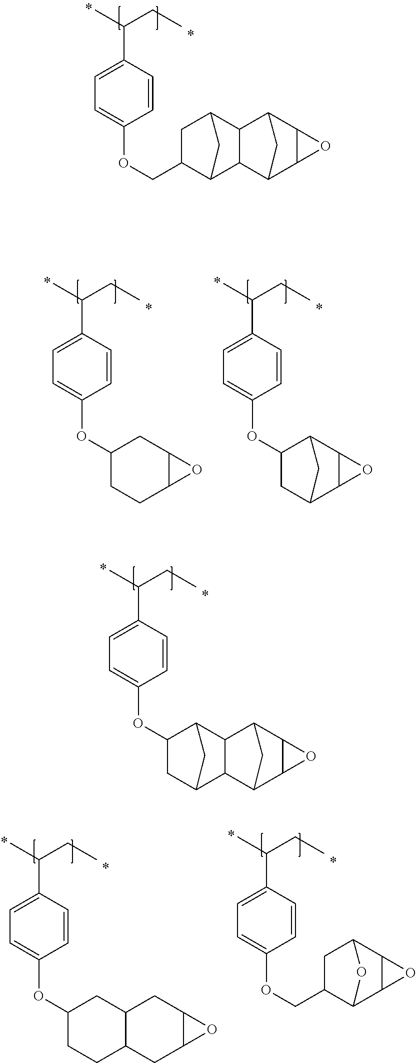

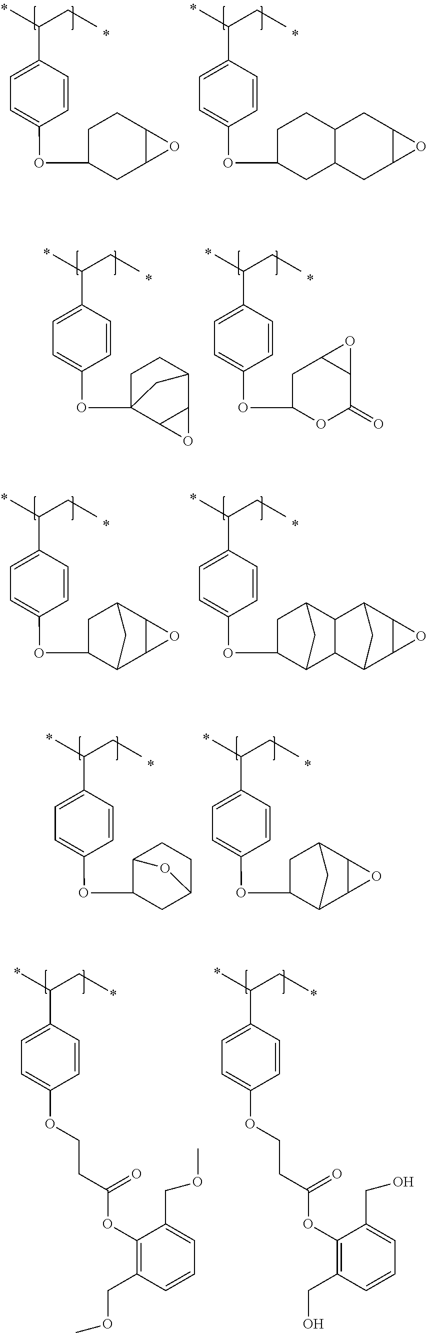

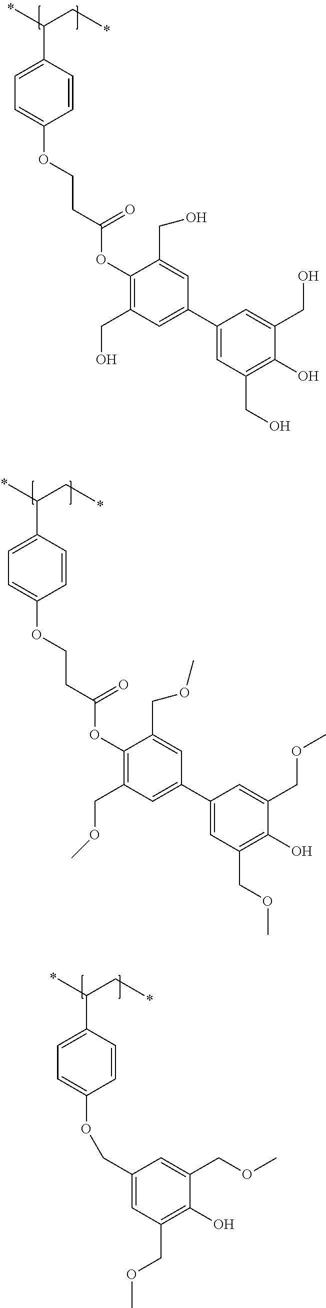

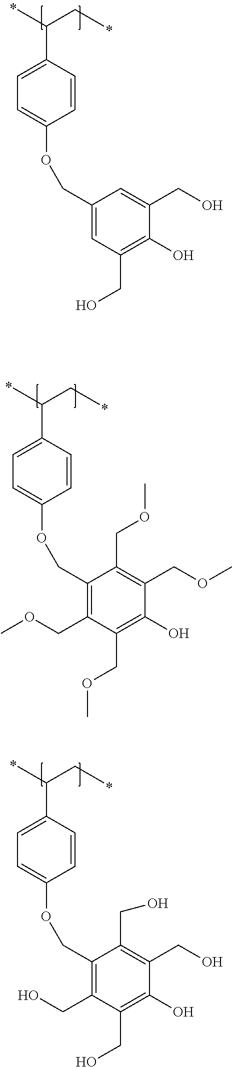

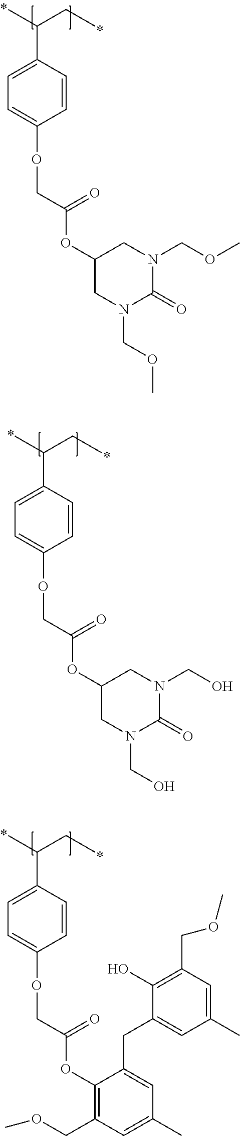

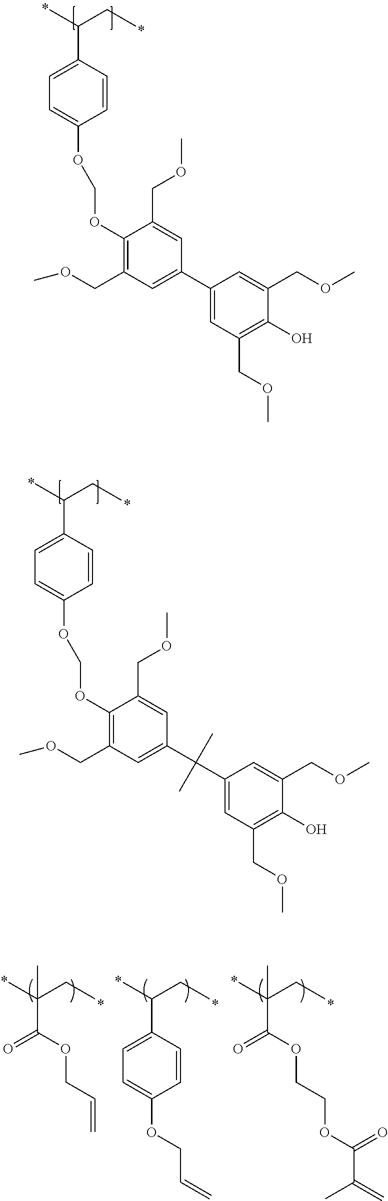

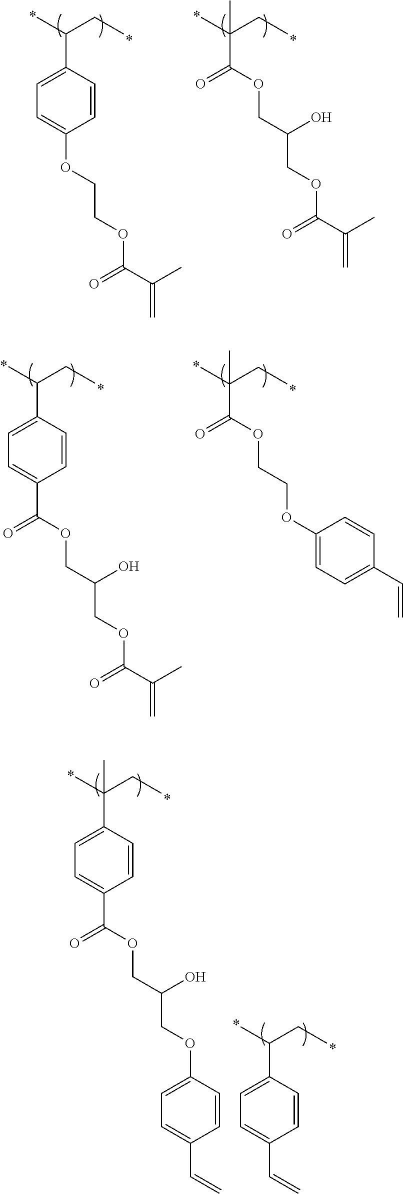

The repeating unit represented by formula (R1-1) preferably contains no aromatic ring from a viewpoint of exhibiting favorable thermal decomposability during heating. Among these units, particularly preferable ones are presented below. Hereinafter, Me represents a methyl group. * represents a bond.

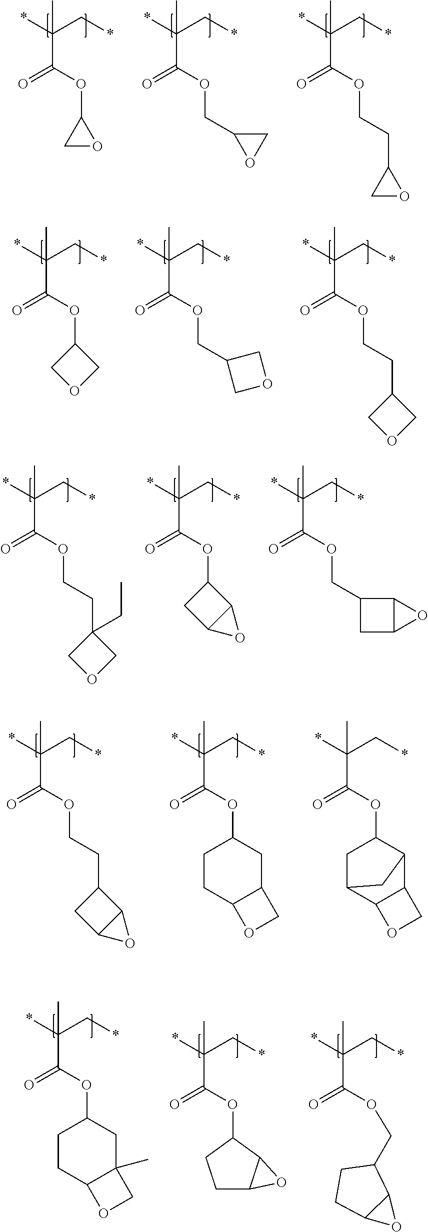

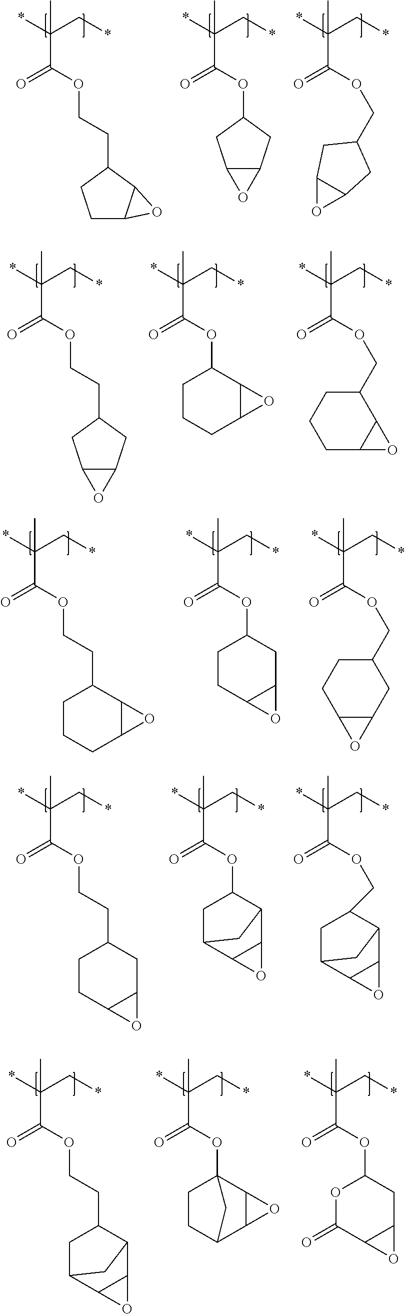

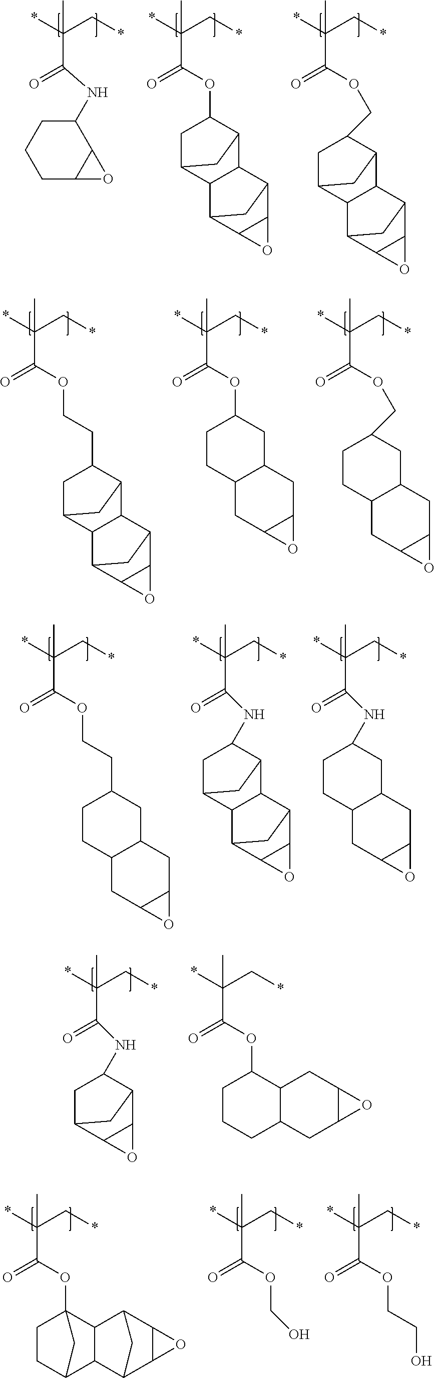

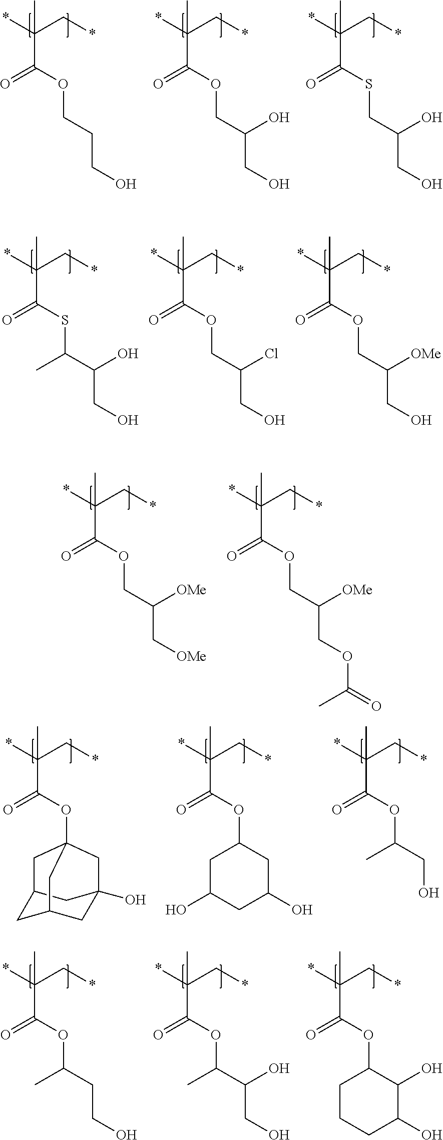

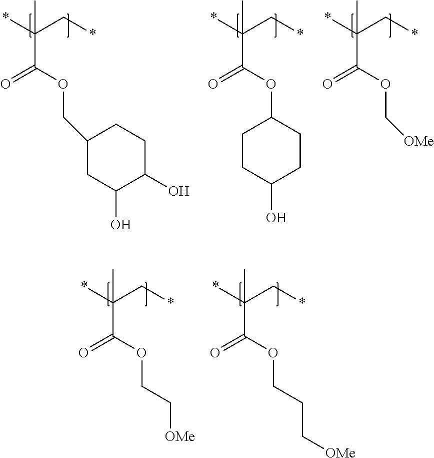

### <<<Formula (R1-2)>>>

The repeating unit (R1) preferably further contains a repeating unit represented by the following formula (R1-2) from a viewpoint of suitably obtaining the effect of the present invention.

When the repeating unit (R1) contains a repeating unit represented by formula (R1-1) and a repeating unit represented by formula (R1-2), X¹ in formula (R1-1) is preferably a group having at least one of an epoxy group and an oxetanyl group.

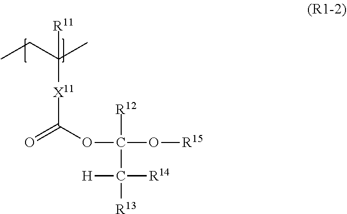

(In formula (R1-2), X¹¹ represents a single bond or a divalent organic group; R¹¹ represents a hydrogen atom, a halogen atom, or an alkyl group; R¹² to R¹⁴ each independently represent a hydrogen atom or an alkyl group having 1 to 10 carbon atoms; R¹⁵ represents an alkyl group having 1 to 10 carbon atoms; and R¹⁴ and R¹⁵ may be bonded to each other to form a ring.).

The repeating unit (R1-2) has a hemiacetal ester structure, and is easily decomposed in the presence of a catalyst to generate a carboxyl group. For example, by a reaction between the generated carboxyl group and an oxirane ring or an oxetane ring, the addition polymer can be easily thermally cured to form a crosslinked structure that is hardly softened.

Examples of the divalent organic group in X¹¹ include a phenylene group.

Examples of the alkyl group in R¹¹ include an alkyl group having 1 to 10 carbon atoms, and an alkyl group having 1 to 4 carbon atoms is preferable.

Examples of the alkyl group having 1 to 10 carbon atoms in R¹¹ to R¹⁵ include a methyl group, an ethyl group, a normal butyl group, a normal octyl group, an isopropyl group, a tert-butyl group, a 2-ethylhexyl group, and a cyclohexyl group.

R¹⁴ and R¹⁵ may be bonded to each other to form a ring, and examples of the ring thus formed include a tetrahydrofuran ring and a tetrahydropyran ring.

A monomer that gives a repeating unit represented by formula (R1-2) to the addition polymer can be synthesized, for example, by a method described in paragraphs [0012] to [0015] of JP 5077564 B2.

Examples of a monomer that gives a repeating unit represented by formula (R1-2) to the addition polymer include a hemiacetal methacrylate compound and a hemiacetal acrylate compound.

Examples of the hemiacetal methacrylate compound include 1-methoxyethyl methacrylate, 1-ethoxyethyl methacrylate, 1-isopropoxyethyl methacrylate, 1-normal butoxyethyl methacrylate, 1-normal hexyloxyethyl methacrylate, and tetrahydro-2H-pyran-2-yl-methacrylate.

Examples of the hemiacetal acrylate compound include 1-methoxyethyl acrylate, 1-tert-butoxyethyl acrylate, 1-isopropoxyethyl acrylate, 1-normal butoxyethyl acrylate, and tetrahydro-2H-pyran-2-yl-acrylate.

### <<Repeating Unit (R2)>>

The repeating unit (R2) of the addition polymer is not particularly limited as long as it has an easily thermally decomposable moiety.

The repeating unit (R2) preferably contains a repeating unit represented by the following formula (R2-1) from a viewpoint of suitably obtaining the effect of the present invention:

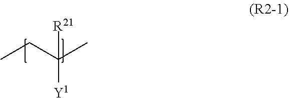

(In formula (R2-1), R²¹ represents an alkyl group; and Y¹ represents a group represented by the following formula (R2-1-1), a phenyl group which may have a substituent, an alkyl group which may be halogenated, a monovalent alicyclic hydrocarbon group which may have a substituent, an alkylcarbonyloxy group which may be halogenated, an alkoxy group which may be halogenated, a nitrile group, or a halogen atom.)

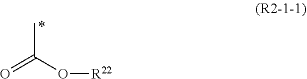

(In formula (R2-1-1), R²² represents a hydrocarbon group which may have a substituent of at least one of a halogen atom and a dialkylamino group; and * represents a bond.).

Examples of R²¹ include an alkyl group having 1 to 4 carbon atoms. Examples of R²¹ include a methyl group.

The number of carbon atoms of R²² in formula (R2-1-1) is, for example, 1 to 15.

Examples of the hydrocarbon group of R²² include an alkyl group, an alkenyl group, an aryl group, and an aralkyl group.

The group represented by formula (R2-1-1) is preferably a primary alkyl ester. That is, the group represented by formula (R2-1-1) is preferably a group represented by the following formula (R2-1-1-1).

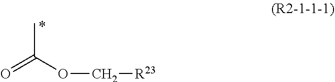

(In formula (R2-1-1-1), R²³ represents a hydrogen atom or a hydrocarbon group which may have a substituent of a halogen atom or a dialkylamino group. * represents a bond.)

Examples of R²² include a methyl group, an ethyl group, a n-propyl group, a n-butyl group, a pentyl group, a hexyl group, an octyl group, a decyl group, a dodecyl group, a tetradecyl group, a hexadecyl group, an octadecyl group, an i-butyl group, an isoamyl group, a cyclohexyl group, a 2-ethylhexyl group, a benzyl group, a phenethyl group, a 2-chloroethyl group, and a 2,2-diaminoethyl group.

Examples of a substituent in the phenyl group which may have a substituent in Y¹ include a halogen atom. That is, R²¹ may be a phenyl group which may be halogenated.

The number of carbon atoms of the alkyl group which may be halogenated in Y¹ is, for example, 1 to 6.

Examples of a substituent in the monovalent alicyclic hydrocarbon group which may have a substituent in Y¹ include a halogen atom. Examples of the monovalent alicyclic hydrocarbon group include a cyclohexyl group and a cyclopentyl group.

The number of carbon atoms of the alkylcarbonyloxy group which may be halogenated in Y¹ is, for example, 2 to 6.

The number of carbon atoms of the alkoxy group which may be halogenated in Y¹ is, for example, 1 to 6.

The repeating unit (R2) preferably contains no aromatic ring from a viewpoint of suitably obtaining the effect of the present invention.

Examples of a monomer that gives the repeating unit (R2) to the addition polymer include the following monomers. methyl methacrylate, ethyl methacrylate, n-propyl methacrylate, n-butyl methacrylate, pentyl methacrylate, hexyl methacrylate, octyl methacrylate, decyl methacrylate, dodecyl methacrylate, tetradecyl methacrylate, hexadecyl methacrylate, octadecyl methacrylate, i-butyl methacrylate, isoamyl methacrylate, cyclohexylmethyl methacrylate, 2-ethylhexyl methacrylate, benzyl methacrylate, phenethyl methacrylate, 2-chloroethyl methacrylate, 2,2-diaminoethyl methacrylate
α-methylstyrene
isobutene, diisobutylene
α-methylvinylcyclohexane, α-methylvinylcyclopentane,
limonene
isopropenyl acetate
α-methylvinyl alkyl ether
methacrylonitrile

The addition polymer may have a repeating unit other than the repeating unit (R1) having a thermosetting moiety and the repeating unit (R2) having an easily thermally decomposable moiety. Examples of a monomer that gives such a repeating unit include 9-anthrylmethyl methacrylate.

The addition polymer more preferably contains no aromatic ring from a viewpoint of suitably obtaining the effect of the present invention.

A content ratio of the repeating unit (R1) in the addition polymer is not particularly limited, but is preferably 5 mol % to 50 mol %, and more preferably 10 mol % to 30 mol % with respect to all repeating units of the addition polymer from a viewpoint of suitably obtaining the effect of the present invention.

A content ratio of the repeating unit (R2) in the addition polymer is not particularly limited, but is preferably 50 mol % to 95 mol %, and more preferably 70 mol % to 90 mol % with respect to all repeating units of the addition polymer from a viewpoint of suitably obtaining the effect of the present invention.

A total content ratio of the repeating unit (R1) and the repeating unit (R2) in the addition polymer is not particularly limited, but is preferably 80 mol % to 100 mol %, more preferably 90 mol % to 100 mol %, and particularly preferably 95 mol % to 100 mol % with respect to all repeating units of the addition polymer from a viewpoint of suitably obtaining the effect of the present invention.

A weight average molecular weight of the addition polymer is not particularly limited, but is preferably 1,000 to 100,000, more preferably 2,000 to 50,000, and particularly preferably 3,000 to 10,000.

The content of the addition polymer in the cavity forming composition is not particularly limited, but is preferably 50% by mass to 100% by mass, more preferably 80% by mass to 100% by mass, and particularly preferably 95% by mass to 100% by mass with respect to a nonvolatile component (that is, a component excluding the solvent) in the cavity forming composition. Note that when the cavity forming composition contains a thermally curing catalyst that promotes thermal curing of the thermosetting moiety, an upper limit of the content of the addition polymer is preferably 99.9% by mass or less.

### <<Method for Manufacturing Addition Polymer>>

A polymerization method for manufacturing the addition polymer is not particularly limited, but the addition polymer can be manufactured, for example, by dissolving a monomer having an ethylenically unsaturated bond and a chain transfer agent to be added as necessary in an organic solvent, then adding a polymerization initiator thereto to perform a polymerization reaction, and then adding a polymerization terminator thereto as necessary.

An addition amount of the polymerization initiator is, for example, 1 to 10% by mass with respect to the mass of the monomer.

An addition amount of the polymerization terminator is, for example, 0.01 to 0.2% by mass with respect to the mass of the monomer.

The organic solvent to be used is not particularly limited, but examples thereof include propylene glycol monomethyl ether, propylene glycol monopropyl ether, ethyl lactate, and dimethylformamide.

Examples of the chain transfer agent to be used include dodecanethiol and dodecylthiol.

Examples of the polymerization initiator to be used include azobisisobutyronitrile, azobiscyclohexanecarbonitrile, and dimethyl azobis(isobutyrate).

Examples of the polymerization terminator to be used include 4-methoxyphenol.

A reaction temperature is, for example, 30 to 100° C.

A reaction time is, for example, 1 to 48 hours.

### <Solvent>

The solvent used in the cavity forming composition is not particularly limited as long as it is a solvent capable of uniformly dissolving solid contained components at normal temperature, but is preferably an organic solvent generally used in a chemical solution for a semiconductor lithography step. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxy cyclopentane, anisole, γ-butyrolactone, N-methylpyrrolidone, N,N-dimethylformamide, and N,N-dimethylacetamide. These solvents can be used singly or in combination of two or more types thereof.

Among these solvents, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

### <Curing Catalyst>

The cavity forming composition may contain a curing catalyst in order to promote a reaction of the thermosetting moiety.

Examples of the curing catalyst include:
a phosphine such as triphenylphosphine, tributylphosphine, tris(4-methylphenyl) phosphine, tris(4-nonylphenyl) phosphine, tris(4-methoxyphenyl) phosphine, tris(2,6-dimethoxyphenyl) phosphine, or triphenylphosphine triphenylborane;
a quaternary phosphonium salt such as tetraphenylphosphonium chloride, tetraphenylphosphonium bromide, benzyltriphenylphosphonium chloride, benzyltriphenylphosphonium bromide, ethyltriphenylphosphonium chloride, ethyltriphenylphosphonium bromide, tetraphenylphosphonium tetraphenylborate, tetraphenylphosphonium tetra(4-methylphenyl) borate, tetraphenylphosphonium tetra(4-methoxyphenyl) borate, or tetraphenylphosphonium tetra(4-fluorophenyl) borate;
a quaternary ammonium salt such as tetraethylammonium chloride, benzyltrimethylammonium chloride, benzyltrimethylammonium bromide, benzyltriethylammonium chloride, benzyltriethylammonium bromide, benzyltripropylammonium chloride, benzyltripropylammonium bromide, tetramethylammonium chloride, tetraethylammonium bromide, tetrapropylammonium chloride, or tetrapropylammonium bromide;
an imidazole such as 2-methylimidazole or 2-ethyl-4-methylimidazole;
an imidazolium salt such as 2-ethyl-4-methylimidazole tetraphenylborate;
a diazabicycloalkene such as 1,8-diazabicyclo [5.4.0]-7-undecene or 1,5-diazabicyclo [4.3.0]-5-nonene; and
an organic acid salt of a diazabicycloalkene, such as a formate of 1,8-diazabicyclo [5.4.0]-7-undecene, a 2-ethylhexanoate of 1,8-diazabicyclo [5.4.0]-7 undecene, a p-toluenesulfonate of 1,8-diazabicyclo [5.4.0]-7-undecene, or a 2-ethylhexanoate of 1,5-diazabicyclo [4.3.0]-5-nonene.

In addition, the curing catalyst may be, for example, a sulfonic acid compound or a carboxylic acid compound.

Examples of the sulfonic acid compound include p-toluenesulfonic acid, pyridinium trifluoromethanesulfonate, pyridinium-p-toluenesulfonate, 5-sulfosalicylic acid, 4-chlorobenzenesulfonic acid, 4-hydroxybenzenesulfonic acid, pyridinium-4-hydroxybenzenesulfonate, n-dodecylbenzenesulfonic acid, 4-nitrobenzenesulfonic acid, benzenedisulfonic acid, 1-naphthalenesulfonic acid, trifluoromethanesulfonic acid, and camphorsulfonic acid.

Examples of the carboxylic acid compound include salicylic acid, citric acid, benzoic acid, and hydroxybenzoic acid.

Examples of a commercially available product of the curing catalyst include: HISHICOLIN [registered trademark] PX-4C, HISHICOLIN PX-4B, HISHICOLIN PX-4MI, HISHICOLIN PX-412B, HISHICOLIN PX-416B, HISHICOLIN PX-2B, HISHICOLIN PX-82B, HISHICOLIN PX-4BT, HISHICOLIN PX-4MP, HISHICOLIN PX-4ET, and HISHICOLIN PX-4PB (which were manufactured by Nippon Chemical Industrial Co., Ltd.); HOKKO-TPP [registered trademark], TPTP [registered trademark], DPCP [registered trademark], TPP-EB [registered trademark], TPP-ZC [registered trademark], DPPB [registered trademark], EMZ-K [registered trademark], DBNK [registered trademark], TPP-MK [registered trademark], TPP-K [registered trademark], TPP-S [registered trademark], TPP-SCN [registered trademark], TPP-DCA [registered trademark], TPPB-DCA [registered trademark], TPP-PB [registered trademark], Hokko TBP-BB [registered trademark], TBPDA [registered trademark], TPPO [registered trademark], PPQ [registered trademark], TOTP [registered trademark], TMTP [registered trademark], TPAP [registered trademark], DPCP [registered trademark], TCHP [registered trademark], Hokko TBP [registered trademark], TTBuP [registered trademark], TOCP [registered trademark], DPPST [registered trademark], TBPH [registered trademark], TPP-MB [registered trademark], TPP-EB [registered trademark], TPP-BB [registered trademark], TPP-MOC [registered trademark], TPP-ZC [registered trademark], and TTBuP-K [registered trademark] (which were manufactured by Hokko Chemical Industry Co., Ltd.); CUREZOL [registered trademark] SIZ, CUREZOL 2MZ-H, CUREZOL C11Z, CUREZOL 1.2DEMZ, CUREZOL 2E4MZ, CUREZOL 2PZ, CUREZOL 2PZ-PW, CUREZOL 2P4MZ, CUREZOL 1B2MZ, CUREZOL 1B2PZ, CUREZOL 2MZ-CN, CUREZOL C11Z-CN, CUREZOL 2E4MZ-CN, CUREZOL 2PZ-CN, CUREZOL C11Z-CNS, CUREZOL 2PZCNS-PW, 2MZA-PW, C11Z-A, CUREZOL 2E4MZ-A, CUREZOL 2MA-OK, CUREZOL 2PZ-OK, CUREZOL 2PHZ-PW, CUREZOL 2P4MHZ, CUREZOL TBZ, CUREZOL SFZ, and CUREZOL 2PZL-T (which were manufactured by Shikoku Chemicals Corporation), U-CAT [registered trademark] SA1, U-CAT SA102, U-CAT SA102-50, U-CAT SA106, U-CAT SA112, U-CAT SA506, U-CAT SA603, U-CAT SA810, U-CAT SA831, U-CAT SA841, U-CAT SA851, U-CAT 881, U-CAT 5002, U-CAT 5003, U-CAT 3512T, U-CAT 3513N, U-CAT 18X, U-CAT 410, U-CAT 1102, U-CAT 2024, U-CAT 2026, U-CAT 2030, U-CAT 2110, U-CAT 2313, U-CAT 651M, U-CAT 660M, U-CAT 420A, DBU [registered trademark], DBN, and POLYCAT8 (which were manufactured by San-Apro Ltd.).

Examples of a commercially available product of a crosslinking catalyst include K-PURE [registered trademark] CXC-1612, K-PURE CXC-1614, K-PURE TAG-2172, K-PURE TAG-2179, K-PURE TAG-2678, and K-PURE TAG2689 (which were manufactured by King Industries), and SI-45, SI-60, SI-80, SI-100, SI-110, and SI-150 (which were manufactured by Sanshin Chemical Industry Co., Ltd.).

These curing catalysts may be used singly or in combination of two or more types thereof.

The content of the curing catalyst in the cavity forming composition is not particularly limited, but is, for example, 0.005% by mass to 10% by mass, and preferably 0.1% by mass to 5% by mass with respect to the addition polymer.

### <Stabilizer>

The cavity forming composition may contain a stabilizer for improving storage stability. This stabilizer is particularly preferably a tertiary amine in order to alleviate an effect of an acid generated by deterioration of the curing catalyst over time.

More preferable examples thereof include tribenzylamine, triethylamine, tripropylamine, tributylamine, trimethanolamine, triethanolamine, and tributanolamine.

The content of the stabilizer in the cavity forming composition is not particularly limited, but is, for example, 3% by mass to 120% by mass, and preferably 3% by mass to 35% by mass with respect to the curing catalyst.

### <Other Components>

A surfactant can be further added to the cavity forming composition in order to further improve a coating property for surface unevenness without generating a pinhole, a striation, and the like. Examples of the surfactant include: a polyoxyethylene alkyl ether such as polyoxyethylene lauryl ether, polyoxyethylene stearyl ether, polyoxyethylene cetyl ether, or polyoxyethylene oleyl ether; a polyoxyethylene alkyl allyl ether such as polyoxyethylene octyl phenol ether or polyoxyethylene nonyl phenol ether; a polyoxyethylene/polyoxypropylene block copolymer; a sorbitan fatty acid ester such as sorbitan monolaurate, sorbitan monopalmitate, sorbitan monostearate, sorbitan monooleate, sorbitan trioleate, or sorbitan tristearate; a nonionic surfactant such as a polyoxyethylene sorbitan fatty acid ester such as polyoxyethylene sorbitan monolaurate, polyoxyethylene sorbitan monopalmitate, polyoxyethylene sorbitan monostearate, polyoxyethylene sorbitan trioleate, or polyoxyethylene sorbitan tristearate; a fluorine-based surfactant such as F-top EF301, EF303, and EF352 (trade names, manufactured by TOCHEM PRODUCTS CO., LTD.), Megafac F171, F173, R-30, and R-40 (trade names, manufactured by DIC Corporation), Fluorad FC430 and FC431 (trade names, manufactured by Sumitomo 3M Limited), or AsahiGuard AG710, Surflon S-382, SC101, SC102, SC103, SC104, SC105, and SC106 (trade names, manufactured by Asahi Glass Co., Ltd.); and organosiloxane polymer KP341 (manufactured by Shin-Etsu Chemical Co., Ltd.). A blending amount of these surfactants is usually 2.0% by mass or less, and preferably 1.0% by mass or less with respect to the total solid content of the protective film forming composition. These surfactants may be added singly or in combination of two or more types thereof.

A nonvolatile component contained in the cavity forming composition, that is, a component excluding the solvent is, for example, 0.01% by mass to 10% by mass.

### (Method for Manufacturing Semiconductor Element)

A method for manufacturing a semiconductor element of the present invention includes the following steps (A) to (D).
Step (A): a step of applying the cavity forming composition of the present invention onto a semiconductor substrate on which conductive wiring patterns are formed.
Step (B): a step of heating the semiconductor substrate to a temperature equal to or higher than a temperature at which the thermosetting moiety is thermally cured and lower than a temperature at which the easily thermally decomposable moiety is thermally decomposed after the step (A) to form a cavity forming curing material (cured cavity forming material) formed of the cavity forming composition between the conductive wiring patterns
Step (C): a step of forming an insulating layer on the conductive wiring patterns and the cavity forming curing material between the conductive wiring patterns after the step (B)
Step (D): a step of heating the semiconductor substrate to a temperature equal to or higher than a temperature at which the easily decomposable moiety is thermally decomposed after the step (C) to burn out the cavity forming curing material.

### <Step (A)>

The step (A) is a step of applying the cavity forming composition of the present invention onto a semiconductor substrate on which conductive wiring patterns are formed.

Examples of the semiconductor substrate include a silicon wafer, a germanium wafer, and a compound semiconductor wafer such as gallium arsenide, indium phosphide, gallium nitride, indium nitride, or aluminum nitride.

The material, size, and shape of the conductive wiring pattern are not particularly limited.

Examples of the material of the conductive wiring pattern include copper, cobalt, ruthenium, molybdenum, chromium, tungsten, manganese, rhodium, nickel, palladium, platinum, silver, gold, and aluminum.

An insulating layer may be formed on the conductive wiring pattern.

Examples of the material of the insulating layer include silicon dioxide, silicon oxycarbide, silicon oxynitride, silicon nitride, silicon carbon nitride (SiCN), aluminum nitride, aluminum oxynitride, and aluminum oxide.

Examples of a method for forming the insulating layer include vapor deposition.

The line width of each wire of the conductive wiring pattern is not particularly limited, but is, for example, 3 nm to 50 nm.

The width of a space between the wires of the conductive wiring pattern is not particularly limited, but is, for example, 3 nm to 50 nm.

A method for forming the conductive wiring pattern is not particularly limited, and for example, a conventionally known lithography process can be used.

The cavity forming composition is applied onto, for example, a semiconductor substrate by an appropriate application method such as a spinner or a coater.

### <Step (B)>

The step (B) is a step of heating the semiconductor substrate to a temperature equal to or higher than a temperature at which the thermosetting moiety is thermally cured and lower than a temperature at which the easily thermally decomposable moiety is thermally decomposed after the step (A) to form a cavity forming curing material (cured cavity forming material) formed of the cavity forming composition between the conductive wiring patterns

The semiconductor substrate is heated using, for example, a heating means such as a hot plate.

In the step (B), the semiconductor substrate is heated to a temperature equal to or higher than a temperature at which the thermosetting moiety is thermally cured and lower than a temperature at which the easily thermally decomposable moiety is thermally decomposed, whereby the thermosetting moiety in the addition polymer reacts to form a crosslinked structure of the addition polymer. As a result, a cavity forming curing material (cured cavity forming material) is obtained from the cavity forming composition.

The heating temperature here can be appropriately selected according to the type of the thermosetting moiety, the type of the curing catalyst optionally contained in the cavity forming composition, and the like, but is preferably 180° C.; to 250° C., more preferably 190° C.; to 240° C., and particularly preferably 200° C.; to 230° C.

A heating time is not particularly limited, but is preferably 0.5 minutes to 10 minutes, and more preferably 0.5 minutes to 5 minutes.

### <Step (C)>

The step (C) is a step of forming an insulating layer on the conductive wiring patterns and the cavity forming curing material between the conductive wiring patterns after the step (B)

The material of the insulating layer is not particularly limited, and may be an organic material or an inorganic material. When the insulating layer is formed of an inorganic material, examples of the material include silicon dioxide, silicon oxycarbide, silicon oxynitride, silicon nitride, silicon carbon nitride (SiCN), aluminum nitride, aluminum oxynitride, aluminum oxide, tantalum oxide, titanium oxide, yttrium oxide, lanthanum oxide, hafnium oxide, zirconium oxide, and mixtures thereof.

The thickness of the insulating layer is not particularly limited, but is, for example, 0.2 nm to 10 nm.

A method for forming the insulating layer is not particularly limited, but a chemical vapor deposition method (CVD method) is preferable.

That is, in the step (C), the insulating layer is preferably formed by chemical vapor deposition.

### <Step (D)>

The step (D) is a step of heating the semiconductor substrate to a temperature equal to or higher than a temperature at which the easily decomposable moiety is thermally decomposed after the step (C) to burn out the cavity forming curing material.

When the cavity forming curing material is heated to a temperature equal to or higher than a temperature at which the easily decomposable moiety is thermally decomposed, a crosslinked product of the addition polymer which is the cavity forming curing material is decomposed due to the thermal decomposition of the easily decomposable moiety.

The heating temperature here is not particularly limited as long as it is a temperature at which the cavity forming curing material disappears, and can be appropriately selected according to the type of the addition polymer and the like, but is preferably 300° C.; to 500° C., more preferably 350° C.; to 450° C., and particularly preferably 370° C.; to 430° C.

A heating time is not particularly limited, but is preferably 5 minutes to 120 minutes, and more preferably 10 minutes to 60 minutes.

A burning amount (decomposition ratio) of the cavity forming curing material is desirably 100%, but does not have to be 100%, and may be 99.9% or less. The decomposition ratio is preferably 90% or more, and more preferably 95% or more.

### <Step (E)>

In the step (B), the cavity forming curing material may be formed also on the conductive wiring patterns. In this case, the method for manufacturing a semiconductor element preferably includes a step (E) of removing the cavity forming curing material on the conductive wiring patterns before the step (C).

The cavity forming curing material on the conductive wiring pattern can be removed by, for example, etching the cavity forming curing material. The etching may be wet etching or dry etching.

### <Step (F)>

A step (F) of removing an uncured cavity forming material which is present on the conductive wiring patterns and is formed of the cavity forming composition may be included between the step (A) and the step (B).

The uncured cavity forming material on the conductive wiring patterns can be removed, for example, by etching the uncured cavity forming material formed of the cavity forming composition. The etching may be wet etching or dry etching.

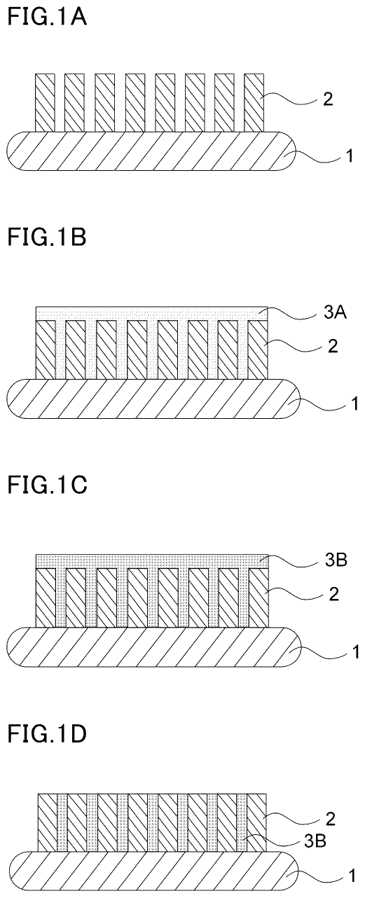

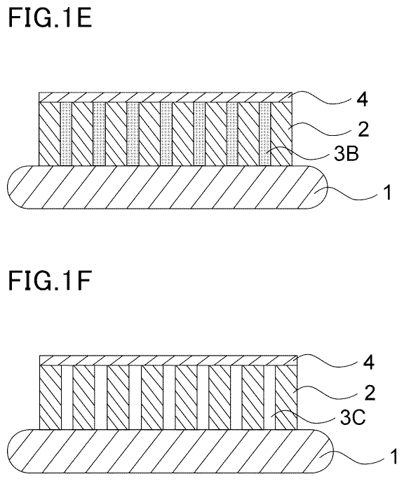

Hereinafter, an example of the method for manufacturing a semiconductor element will be described with reference to FIGS. 1A to 1F.

First, as illustrated in FIG. 1A, a semiconductor substrate 1 on which conductive wiring patterns 2 are formed is prepared.

Subsequently, as the step (A), the cavity forming composition is applied onto the semiconductor substrate 1 on which the conductive wiring patterns 2 are formed. As a result, an uncured cavity forming material 3A is formed on the conductive wiring patterns 2 and in a gap between the conductive wiring patterns 2 (FIG. 1B).

Subsequently, as the step (B), the semiconductor substrate 1 is heated to a temperature equal to or higher than a temperature at which the thermosetting moiety is thermally cured and lower than a temperature at which the easily thermally decomposable moiety is thermally decomposed. As a result, the uncured cavity forming material 2A on the conductive wiring patterns 2 and in a gap between the conductive wiring patterns 2 is cured to form a cured cavity forming material 3B (cavity forming curing material) (FIG. 1C).

Subsequently, as the step (E), the cured cavity forming material 3B on the conductive wiring patterns 2 is removed (FIG. 1D).

Subsequently, as the step (C), an insulating layer 4 is formed on the conductive wiring patterns 2 and the cured cavity forming material 3B in a gap between the conductive wiring patterns 2 (FIG. 1E).

Subsequently, as the step (D), the semiconductor substrate 1 is heated to a temperature equal to or higher than a temperature at which the easily decomposable moiety is thermally decomposed, and the cured cavity forming material 3B between the conductive wiring patterns 2 is burned out to form a cavity 3C between the conductive wiring patterns 2.

As described above, a cavity is formed between the conductive wiring patterns of the semiconductor substrate.

### EXAMPLES

Hereinafter, the contents of the present invention will be described specifically with reference to Examples, but the present invention is not limited thereto.

The weight average molecular weight of a polymer described in the following examples is a measurement result obtained by gel permeation chromatography (hereinafter, abbreviated as GPC). For the measurement, a GPC device manufactured by Tosoh Corporation was used, and measurement conditions and the like are as follows.
Column temperature: 40
Flow rate: 0.35 m1/min
Eluent: tetrahydrofuran (THF)
Standard sample: polystyrene (Tosoh Corporation)

### Synthesis Example 1

Into a reaction container equipped with a thermometer, a cooling tube, a dropping device, and a stirring device, 30.00 g of propylene glycol monomethyl ether acetate was put, and nitrogen was allowed to flow therethrough for 30 minutes. Thereafter, the temperature was raised to 80° C. In another container, 2.10 g of 1-butoxyethyl methacrylate (product of Honshu Chemical Industry Co., Ltd.), 2.00 g of glycidyl methacrylate (product of Tokyo Chemical Industry Co., Ltd.), 11.58 g of methyl methacrylate (product of Tokyo Chemical Industry Co., Ltd.), and 2.32 g of dimethyl azobis(isobutyrate) (product of Fujifilm Wako Pure Chemical Industries, Ltd.) were dissolved in 42.00 g of propylene glycol monomethyl ether acetate, and the resulting solution was put into the dropping container, and added dropwise to the reaction solution of propylene glycol monomethyl ether acetate over 30 minutes under a nitrogen atmosphere.

The resulting mixture was stirred at 80° C.; for 24 hours under a nitrogen atmosphere to obtain a solution containing a copolymer of 1-butoxyethyl methacrylate, glycidyl methacrylate, and methyl methacrylate. The resulting polymer was subjected to GPC analysis, and was found to have a weight average molecular weight Mw of 5420.

A unit structure of the polymer is presented below. The number attached to the unit structure indicates a molar ratio (unit: mol %) of each structural unit in the polymer.

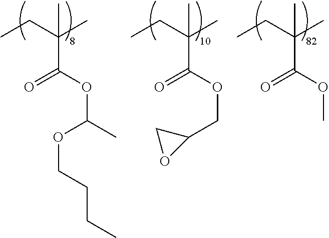

### Synthesis Example 2

Into a reaction container equipped with a thermometer, a cooling tube, a dropping device, and a stirring device, 30.00 g of propylene glycol monomethyl ether acetate was put, and nitrogen was allowed to flow therethrough for 30 minutes. Thereafter, the temperature was raised to 80° C. In another container, 4.10 g of glycidyl methacrylate (product of Tokyo Chemical Industry Co., Ltd.), 11.54 g of methyl methacrylate (product of Tokyo Chemical Industry Co., Ltd.), and 2.37 g of dimethyl azobis(isobutyrate) (product of Fujifilm Wako Pure Chemical Industries, Ltd.) were dissolved in 42.00 g of propylene glycol monomethyl ether acetate, and the resulting solution was put into the dropping container, and added dropwise to the reaction solution of propylene glycol monomethyl ether acetate over 30 minutes under a nitrogen atmosphere.

The resulting mixture was stirred at 80° C.; for 24 hours under a nitrogen atmosphere to obtain a solution containing a copolymer of glycidyl methacrylate and methyl methacrylate. The resulting polymer was subjected to GPC analysis, and was found to have a weight average molecular weight Mw of 7910.

A unit structure of the polymer is presented below. The number attached to the unit structure indicates a molar ratio (unit: mol %) of each structural unit in the polymer.

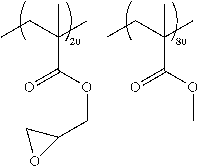

### Synthesis Example 3

Into a reaction container equipped with a thermometer, a cooling tube, a dropping device, and a stirring device, 30.00 g of propylene glycol monomethyl ether acetate was put, and nitrogen was allowed to flow therethrough for 30 minutes. Thereafter, the temperature was raised to 80° C. In another container, 5.60 g of (2-hydroxyethyl) methacrylate (product of Tokyo Chemical Industry Co., Ltd.), 10.05 g of methyl methacrylate (product of Tokyo Chemical Industry Co., Ltd.), and 2.35 g of dimethyl azobis(isobutyrate) (product of Fujifilm Wako Pure Chemical Industries, Ltd.) were dissolved in 42.00 g of propylene glycol monomethyl ether acetate, and the resulting solution was put into the dropping container, and added dropwise to the reaction solution of propylene glycol monomethyl ether acetate over 30 minutes under a nitrogen atmosphere. The resulting mixture was stirred at 80° C.; for 24 hours under a nitrogen atmosphere to obtain a solution containing a copolymer of (2-hydroxyethyl) methacrylate and methyl methacrylate. The resulting polymer was subjected to GPC analysis, and was found to have a weight average molecular weight Mw of 8570.

A unit structure of the polymer is presented below. The number attached to the unit structure indicates a molar ratio (unit: mol %) of each structural unit in the polymer.

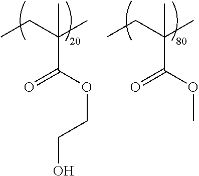

### Synthesis Example 4

Into a reaction container equipped with a thermometer, a cooling tube, a dropping device, and a stirring device, 30.00 g of propylene glycol monomethyl ether acetate was put, and the temperature was raised to 80° C.; under a nitrogen atmosphere. In another container, 15.46 g of methyl methacrylate (product of Tokyo Chemical Industry Co., Ltd.) and 2.53 g of dimethyl azobis(isobutyrate) (product of Fujifilm Wako Pure Chemical Industries, Ltd.) were dissolved in 42.00 g of propylene glycol monomethyl ether acetate, and the resulting solution was put into the dropping container, and added dropwise to the reaction solution of propylene glycol monomethyl ether acetate over 30 minutes under a nitrogen atmosphere.

The resulting mixture was stirred at 80° C.; for 24 hours under a nitrogen atmosphere to obtain a solution containing a polymer of methyl methacrylate. The resulting polymer was subjected to GPC analysis, and was found to have a weight average molecular weight Mw of 6300.

A unit structure of the polymer is presented below. The number attached to the unit structure indicates a molar ratio (unit: mol %) of each structural unit in the polymer.

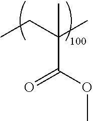

### Example 1

To 10.0 g of the solution containing the polymer obtained in Synthesis Example 1 (solid content concentration: 18.0% by mass), 77.3 g of propylene glycol monomethyl ether acetate was added to obtain a 2.0% by mass solution. Thereafter, the solution was filtered using a polyethylene microfilter having a pore size of 0.05 μm to prepare a cavity forming composition.

### Example 2

To 10.0 g of the solution containing the polymer obtained in Synthesis Example 2 (solid content concentration: 18.9% by mass), 66.6 g of propylene glycol monomethyl ether, 20.4 g of propylene glycol monomethyl ether acetate, and 0.06 g of TAG-2689 (quaternary ammonium salt of trifluoromethanesulfonic acid manufactured by King Industries) were added to obtain a 2.0% by mass solution. Thereafter, the solution was filtered using a polyethylene microfilter having a pore size of 0.2 μm to prepare a cavity forming composition.

### Example 3

To 10.0 g of the solution containing the polymer obtained in Synthesis Example 3 (solid content concentration: 16.5% by mass), 48.6 g of propylene glycol monomethyl ether, 12.5 g of propylene glycol monomethyl ether acetate, and 0.06 g of pyridinium trifluoromethanesulfonate were added to obtain a 2.0% by mass solution. Thereafter, the solution was filtered using a polyethylene microfilter having a pore size of 0.2 μm to prepare a cavity forming composition.

### Example 4

To 10.0 g of the solution containing the polymer obtained in Synthesis Example 2 (solid content concentration: 18.9% by mass), 66.7 g of propylene glycol monomethyl ether, 20.6 g of propylene glycol monomethyl ether acetate, 0.01 g of triethanolamine, and 0.06 g of TAG-2689 (quaternary ammonium salt of trifluoromethanesulfonic acid manufactured by King Industries) were added to obtain a 2.0% by mass solution. Thereafter, the solution was filtered using a polyethylene microfilter having a pore size of 0.2 μm to prepare a cavity forming composition.

### Comparative Example 1

To 10.0 g of the solution containing the polymer obtained in Synthesis Example 4 (solid content concentration: 17.4% by mass), 62.5 g of propylene glycol monomethyl ether acetate was added to obtain a 2.4% by mass solution. Thereafter, the solution was filtered using a polyethylene microfilter having a pore size of 0.2 μm to prepare a cavity forming composition.

### Comparative Example 2

To 5.00 g of a purchased propylene glycol monomethyl ether acetate solution of polyglycidyl methacrylate (product of Maruzen Petrochemical Co., Ltd., molecular weight: 8500, solid content concentration: 30.1% by mass), 19.1 g of propylene glycol monomethyl ether, 41.0 g of propylene glycol monomethyl ether acetate, and 0.05 g of TAG-2689 (quaternary ammonium salt of trifluoromethanesulfonic acid manufactured by King Industries) were added to obtain a 2.4% by mass solution. Thereafter, the solution was filtered using a polyethylene microfilter having a pore size of 0.2 μm to prepare a cavity forming composition.

### (Formation of Coating Film)

Each of the cavity forming compositions prepared in Examples 1 to 4 and the cavity forming compositions prepared in Comparative Examples 1 and 2 was applied onto a silicon substrate by spin coating, and baked at a predetermined baking temperature for 60 seconds to prepare a coating film having a film thickness of 43 nm.

### (Decomposition Performance Test of Composition by Firing)

Each of the cavity forming compositions prepared in Examples 1 to 4 and the cavity forming compositions prepared in Comparative Examples 1 and 2 was applied by spin coating to prepare a coating film on a silicon substrate at a baking temperature presented in Table 1. The coating film had a film thickness of about 43 nm. A thermal decomposition ratio was measured using the obtained coating film.

The baking temperature during film formation and the obtained results of the decomposition ratio are presented in Table 1.

Note that the details of measurement conditions of the thermal decomposition ratio are as follows.

First, the thickness of the coating film was measured using VM-3210 (manufactured by SCREEN Semiconductor Solutions Co., Ltd.). Thereafter, the silicon substrate to which the cavity forming composition had been applied was heated for 30 minutes with a plate preheated to 400° C.; under a nitrogen atmosphere. Finally, the film thickness of the resulting coating film on the substrate was measured again using RE-3100 and RE-3500 (manufactured by SCREEN Semiconductor Solutions Co., Ltd.). From the obtained results, a thermal decomposition ratio of the coating film was calculated using the following formula 1.

$$( Decomposition ratio [ \% ] ) = 100 \times ( 1 - {T}_{1} / {T}_{0} ) \qquad Formula 1$$

T₀=film thickness of coating film before firing decomposition
T₁=film thickness of coating film after firing decomposition

TABLE 1

| | Baking temperature | Decomposition |
|---|---|---|
| | during film formation | ratio [%] |
| Example 1 | 205° C. | 98.6 |
| Example 2 | 215° C. | 98.6 |
| Example 3 | 215° C. | 98.9 |
| Example 4 | 215° C. | 98.6 |
| Comparative Example 1 | 205° C. | 99.5 |
| Comparative Example 2 | 205° C. | 92.8 |

From the results in Table 1 above, it was found that all of the coating films prepared using the cavity forming compositions prepared in Examples 1 to 3 and Comparative Example 1 had higher decomposition ratios than Comparative Example 2.

### (Measurement Test of Glass Transition Temperature)

Each of the cavity forming compositions prepared in Examples 1 to 4 and the cavity forming compositions prepared in Comparative Examples 1 and 2 was applied by spin coating to prepare a coating film on a silicon substrate at a baking temperature presented in Table 2. The coating film had a film thickness of about 43 nm. Then, the coating film was scraped, and the obtained powder was subjected to differential scanning calorimetry. The baking temperature during film formation and the obtained results of the glass transition temperature are presented in Table 2.

Note that the details of measurement conditions of the glass transition temperature are as follows.

For the measurement, differential scanning calorimetry (DSC) was used. First, the temperature was raised to 140° C. to erase a thermal history. Thereafter, the temperature was lowered to 0° C.; at a temperature lowering rate of 20° C./min, and measurement was performed again at a temperature rising rate of 20° C./min. A temperature indicating an inflection point of a transition region appearing stepwise in a thermogram at this time was defined as the glass transition temperature. Note that, for a result that no inflection point was observed, the glass transition temperature was defined as 100° C.; or higher. An apparatus used was Q2000 manufactured by TA Instruments, and a sample amount was about 5 mg.

TABLE 2

| | Baking temperature | Glass transition |
|---|---|---|
| | during film formation | temperature [° C.] |
| Example 1 | 205° C. | 93.1 |
| Example 2 | 215° C. | >100.0 |
| Example 3 | 215° C. | 93.9 |
| Example 4 | 215° C. | >100.0 |
| Comparative Example 1 | 205° C. | 85.4 |
| Comparative Example 2 | 205° C. | >100.0 |

From the results in Table 2 above, it was found that all of the coating films prepared using the protective film forming compositions prepared in Examples 1 to 3 and Comparative Example 2 had higher glass transition temperatures than Comparative Example 1.

### INDUSTRIAL APPLICABILITY

The cavity forming composition according to the present invention has both a high glass transition temperature and thermal decomposability at a high temperature when formed into a coating film, and thus provides a film that promotes formation of a uniform insulating layer on the present composition when applied to processing for forming a cavity between multilayer wires, and is excellent in composition removal performance by firing.

### REFERENCE SIGNS LIST

1 Semiconductor substrate
2 Conductive wiring pattern
3A Uncured cavity forming material
3B Cured cavity forming material
3C Cavity
4 Insulating layer

1. A cavity forming composition for forming a cavity between conductive wiring patterns on a semiconductor substrate, the cavity forming composition comprising:
a solvent; and an addition polymer formed of two or more types of monomers having an ethylenically unsaturated bond, wherein
the addition polymer has a repeating unit (R1) having a thermosetting moiety and a repeating unit (R2) having an easily thermally decomposable moiety, and
a thermal decomposition temperature of the easily thermally decomposable moiety is higher than a thermally curing temperature of the thermosetting moiety.

2. The cavity forming composition according to claim 1, wherein
a cured film obtained by heating a film formed of the cavity forming composition has a glass transition temperature of 86° C. or higher, and
the cured film has a decomposition ratio of 95% or more when heated at 400° C. for 30 minutes in a nitrogen atmosphere.

3. The cavity forming composition according to claim 1, wherein the repeating unit (R1) contains a repeating unit represented by the following formula (R1-1): 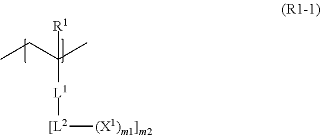
wherein in formula (R1-1), R¹ represents a hydrogen atom, a halogen atom, or an alkyl group;
L¹ and L² each independently represent a single bond or a linking group;
X¹ represents a group having at least one of an epoxy group, an oxetanyl group, a hydroxyalkyl group, an alkoxyalkyl group, a (meth)acryloyl group, a styryl group, and a vinyl group;
m1 represents an integer of 1 to 5, and when m1 is 2 or more, two or more X¹s may be the same or different; and
m2 represents an integer of 1 to 5, and when m2 is 2 or more, two or more [-L²-(X¹)ₘ₁] may be the same or different.

4. The cavity forming composition according to claim 3, wherein the repeating unit (R1) further contains a repeating unit represented by the following formula (R1-2): 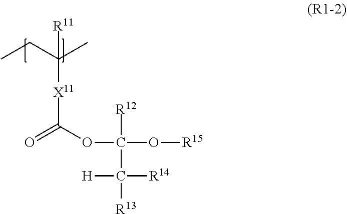
wherein in formula (R1-2), Xⁱⁱ represents a single bond or a divalent organic group; R¹¹ represents a hydrogen atom, a halogen atom, or an alkyl group; R¹² to R¹⁴ each independently represent a hydrogen atom or an alkyl group having 1 to 10 carbon atoms; R¹⁵ represents an alkyl group having 1 to 10 carbon atoms; and R¹⁴ and R¹⁵ may be bonded to each other to form a ring.

5. The cavity forming composition according to claim 1, wherein the repeating unit (R2) contains a repeating unit represented by the following formula (R2-1): 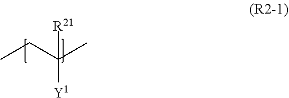
wherein in formula (R2-1), R²¹ represents a hydrogen atom or an alkyl group; and Y¹ represents a group represented by the following formula (R2-1-1), a phenyl group which may have a substituent, an alkyl group which may be halogenated, a monovalent alicyclic hydrocarbon group which may have a substituent, an alkylcarbonyloxy group which may be halogenated, an alkoxy group which may be halogenated, a nitrile group, or a halogen atom: 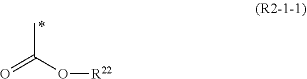
wherein in formula (R2-1-1), R²² represents a hydrocarbon group which may have a substituent of at least one of a halogen atom and a dialkylamino group; and * represents a bond.

6. The cavity forming composition according to claim 1, wherein the repeating unit (R1) in the addition polymer is 5 mol % to 50 mol % with respect to all repeating units of the addition polymer.

7. The cavity forming composition according to claim 1, wherein the repeating unit (R2) in the addition polymer is 50 mol % to 95 mol % with respect to all repeating units of the addition polymer.

8. A method for manufacturing a semiconductor element, the method comprising:
a step (A) of applying the cavity forming composition according to claim 1 onto a semiconductor substrate on which conductive wiring patterns are formed;
a step (B) of heating the semiconductor substrate to a temperature equal to or higher than a temperature at which the thermosetting moiety is thermally cured and lower than a temperature at which the easily thermally decomposable moiety is thermally decomposed after the step (A) to form a cavity forming curing material formed of the cavity forming composition between the conductive wiring patterns;
a step (C) of forming an insulating layer on the conductive wiring patterns and the cavity forming curing material between the conductive wiring patterns after the step (B); and
a step (D) of heating the semiconductor substrate to a temperature equal to or higher than a temperature at which the easily decomposable moiety is thermally decomposed after the step (C) to burn out the cavity forming curing material.

9. The method for manufacturing a semiconductor element according to claim 8, wherein
in the step (B), the cavity forming curing material is formed also on the conductive wiring patterns, and
the method comprises a step (E) of removing the cavity forming curing material on the conductive wiring patterns before the step (C).

10. The method for manufacturing a semiconductor element according to claim 8, the method comprising a step (F) of removing an uncured cavity forming material which is present on the conductive wiring patterns and is formed of the cavity forming composition between the step (A) and the step (B).

11. The method for manufacturing a semiconductor element according to claim 8, wherein in the step (C), the insulating layer is formed by chemical vapor deposition.
